(19) United States
(12) Patent Application Publication
(10) Pub. No.: US 2024/0126259 A1
(43) Pub. Date: Apr. 18, 2024

(54) SYSTEM AND METHOD FOR REDUCING COMMON MODE FAILURES IN FLIGHT CONTROL OF AN AIRCRAFT

(71) Applicant: BETA AIR, LLC, South Burlington, VT (US)

(72) Inventors: Mark Juhrig, SOUTH BURLINGTON, VT (US); Timothy Gerard Richter, SOUTH BURLINGTON, VT (US); Christian Altz, SOUTH BURLINGTON, VT (US)

(73) Assignee: BETA AIR, LLC, SOUTH BURLINGTON, VT (US)

(21) Appl. No.: 17/966,748

(22) Filed: Oct. 14, 2022

(51) Int. Cl. G05D 1/00; G01R 31/00

(52) U.S. Cl. CPC G05D 1/0077; G01R 31/008

(57) ABSTRACT

Systems and methods for reducing common mode failures in flight control of an aircraft is disclosed herein. Reducing common mode failures includes using dissimilar components. Dissimilar components found in flight control of an aircraft may include sensors, effectors, command processors, and monitor processors. One or more flight controllers are used to transmit commands to effectors and monitor effectors using dissimilar sensors.

### FIELD OF THE INVENTION

The present invention generally relates to the field of electric aircraft flight control. In particular, the present invention is directed to a system and method for reducing common mode failures in flight control of an aircraft.

### BACKGROUND

It is important to have redundant features in an aircraft. Redundant features act as backups in case something fails. However, common mode failures may affect all redundant features. Dissimilar components can be used to combat common mode failures. Dissimilar components may perform similar tasks to each other.

### SUMMARY OF THE DISCLOSURE

In an aspect a system for reducing common mode failures in flight control of an aircraft includes a first effector controller connected to a first effector and comprising a first effector CAN port and a second effector CAN port, a first flight controller communicatively connected to the first effector CAN port by a first CAN bus, a second flight controller communicatively connected to the second effector CAN port by a second CAN bus, wherein, the first effector controller is configured to: receive a first command signal from the first flight controller and a second command signal from the second flight controller, detect a first output of the first effector using a first dissimilar sensor, and detect a second output of the first effector using a second dissimilar sensor.

In another aspect a method for reducing common mode failure in flight control of an aircraft includes connecting a first effector controller to a first effector, wherein the first effector comprises a first effector CAN port and a second effector CAN port, communicatively connecting a first flight controller to the first effector CAN port by a first CAN bus, communicatively connecting a second flight controller to the second effector CAN port by a second CAN bus, receiving, by the first effector controller, a first command signal from the first flight controller and a second command signal from the second flight controller, detecting, by the first effector controller, a first output of the first effector using a first dissimilar sensor, and detecting, by the first effector controller, a second output of the first effector using a second dissimilar sensor.

These and other aspects and features of non-limiting embodiments of the present invention will become apparent to those skilled in the art upon review of the following description of specific non-limiting embodiments of the invention in conjunction with the accompanying drawings.

### BRIEF DESCRIPTION OF THE DRAWINGS

For the purpose of illustrating the invention, the drawings show aspects of one or more embodiments of the invention. However, it should be understood that the present invention is not limited to the precise arrangements and instrumentalities shown in the drawings, wherein:

FIG. 1 is a block diagram illustrating an embodiment of a system for redundant flight control configured for use in an aircraft in accordance with aspects of the invention;

FIGS. 2A-2D are various diagrammatic representations of exemplary actuators in use in an aircraft in accordance with aspects of the invention;

FIGS. 3A and 3B are diagrammatic representations of an exemplary aircraft in accordance with aspects of the invention;

FIG. 4 is a block diagram illustrating a system for reducing common mode failures in flight control of an aircraft;

FIG. 5 is an exemplary embodiment of a flight controller;

FIG. 6 is a flow diagram of a method for effector reboot on an electric aircraft during flight; and

FIG. 7 is a block diagram of a computing system that can be used to implement any one or more of the methodologies disclosed herein and any one or more portions thereof.

The drawings are not necessarily to scale and may be illustrated by phantom lines, diagrammatic representations and fragmentary views. In certain instances, details that are not necessary for an understanding of the embodiments or that render other details difficult to perceive may have been omitted.

### DETAILED DESCRIPTION

At a high level, aspects of the present disclosure are directed to systems and methods for reducing common mode failures in flight control of an aircraft. In an embodiment, dissimilar components may be used to reduce common mode failures. Dissimilar components perform substantially similar functions but in different manners to prevent common mode failures. Exemplary embodiments illustrating aspects of the present disclosure are described below in the context of several specific examples.

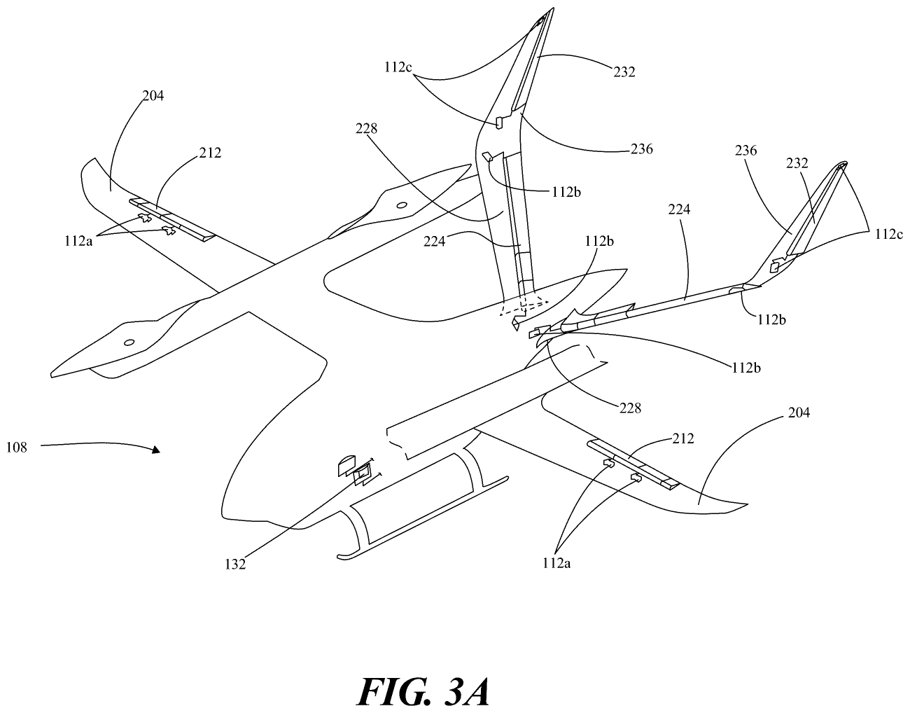

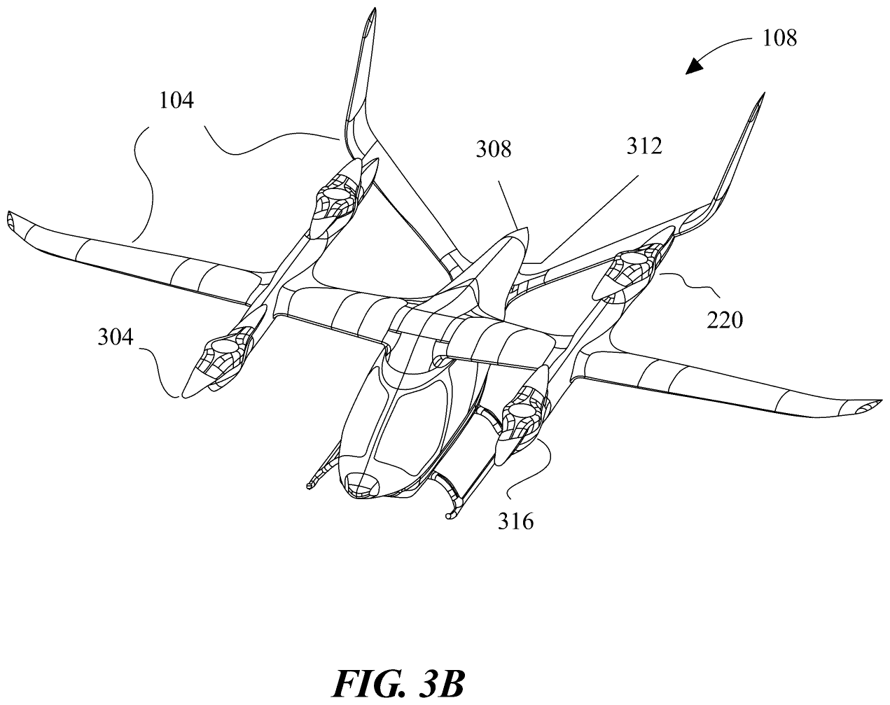

In the following description, for purposes of explanation, numerous details are set forth in order to provide understanding of the present invention. It will be apparent, however, that the present invention may be practiced without these specific details. As used in this disclosure, the word “exemplary” or “illustrative” means “serving as an example, instance, or illustration.” Any implementation described in this disclosure as “exemplary” or “illustrative” is not necessarily to be construed as preferred or advantageous over other implementations. All of the implementations described below are exemplary implementations provided to enable persons skilled in the art to make or use the embodiments of the disclosure and are not intended to limit the scope of the disclosure, which is defined by the claims. For purposes of description in this disclosure, the terms “up”, “down”, “left”, “right”, and derivatives thereof shall relate to the invention as oriented in FIG. 3. Furthermore, there is no intention to be bound by any expressed or implied theory presented in the preceding technical field, background, brief summary, or the following detailed description. It is also to be understood that the specific devices and processes illustrated in the attached drawings, and described in the following specification, are simply exemplary embodiments of the inventive concepts defined in the appended claims. Hence, specific dimensions and other physical characteristics relating to the embodiments disclosed in this disclosure are not to be considered as limiting, unless the claims expressly state otherwise.

“Communicatively connected”, for the purposes of this disclosure, is a process whereby one device, component, or circuit is able to receive data from and/or transmit data to another device, component, or circuit. Communicative connection may be performed by wired or wireless electronic communication, either directly or by way of one or more intervening devices or components. In an embodiment, communicative connection includes electrically connection an output of one device, component, or circuit to an input of another device, component, or circuit. Communicative connection may be performed via a bus or other facility for intercommunication between elements of a computing device. Communicative connection may include indirect connections via “wireless” connection, low power wide area network, radio communication, optical communication, magnetic, capacitive, or optical connection, or the like. In an embodiment, communicative connecting may include electrically connecting an output of one device, component, or circuit to an input of another device, component, or circuit. Communicative connecting may be performed via a bus or other facility for intercommunication between elements of a computing device. Communicative connecting may include indirect connections via “wireless” connection, low power wide area network, radio communication, optical communication, magnetic, capacitive, or optical connection, or the like.

A “flight component” as described in this disclosure, is any aerodynamic surface attached to an aircraft and that interacts with forces to move the aircraft. A flight component may include, as a non-limiting example, ailerons, flaps, leading edge flaps, rudders, elevators, spoilers, slats, blades, stabilizers, stabilators, airfoils, a combination thereof, or any other moveable surface used to control an aircraft in a fluid medium.

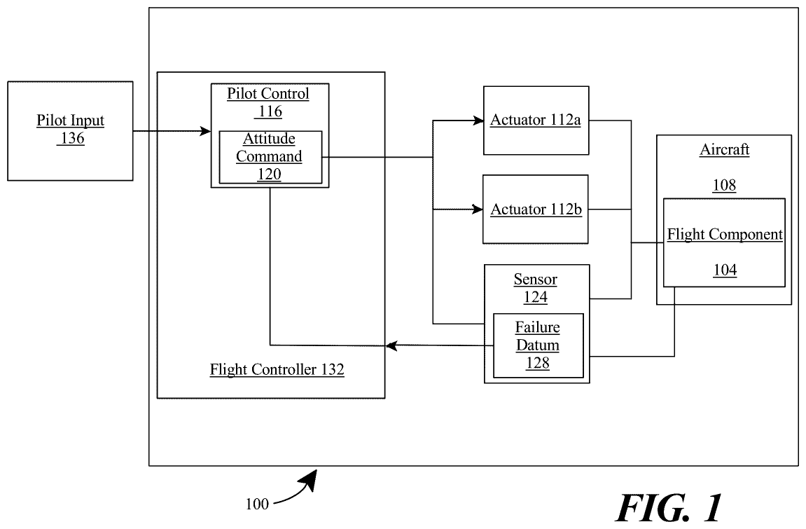

Referring now to FIG. 1, an exemplary embodiment of a system 100 for redundant flight control configured for use in an aircraft is introduced. System 100 includes a flight component 104 attached to an aircraft 108, where a movement of flight component 104 is configured to adjust the attitude of aircraft 108. In one or more embodiments, system 100 includes a plurality of actuators 112 (also referred to in this disclosure as “actuators”), which includes a first actuator 112a and a second actuator 112b. Each of first actuator 112a and second actuator 112b are attached to flight component 104 and configured to move flight component 104.

As understood by one skilled in the art, though actuators 112 are discussed as a pair of actuators, any number of actuators greater than one may be used to provide redundant flight control of an aircraft.

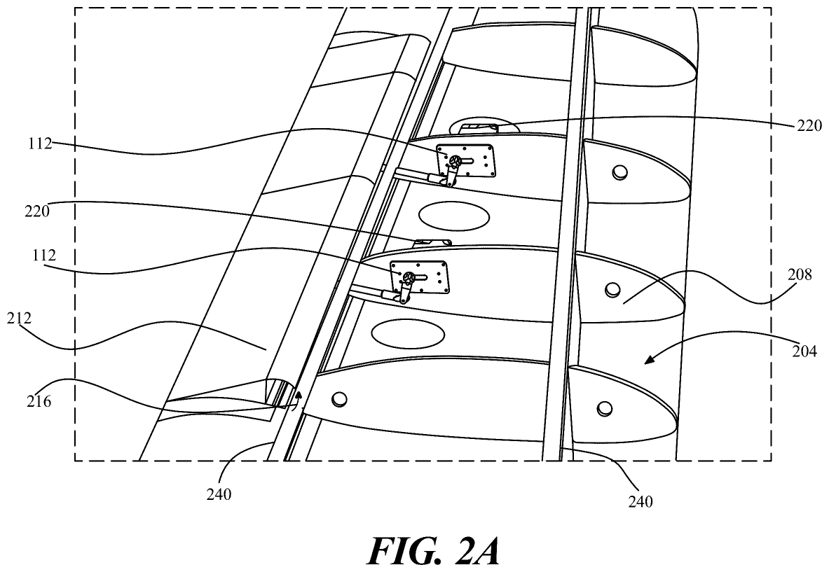

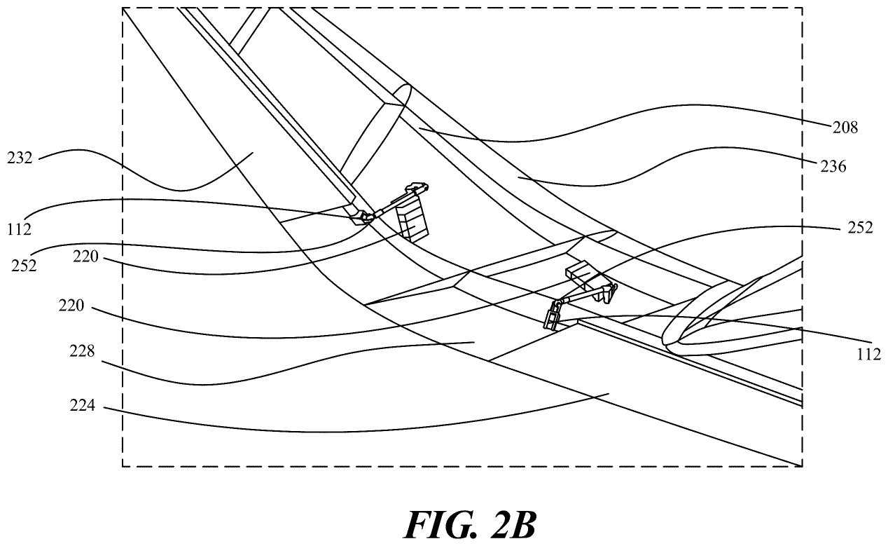

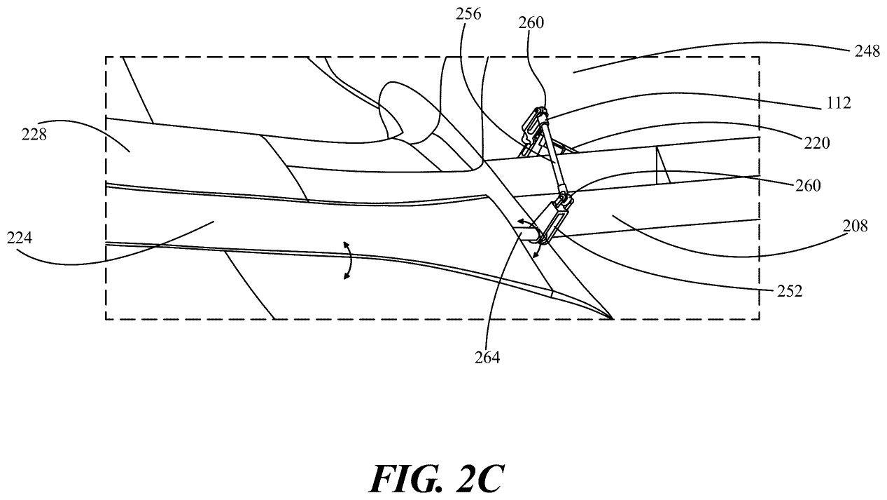

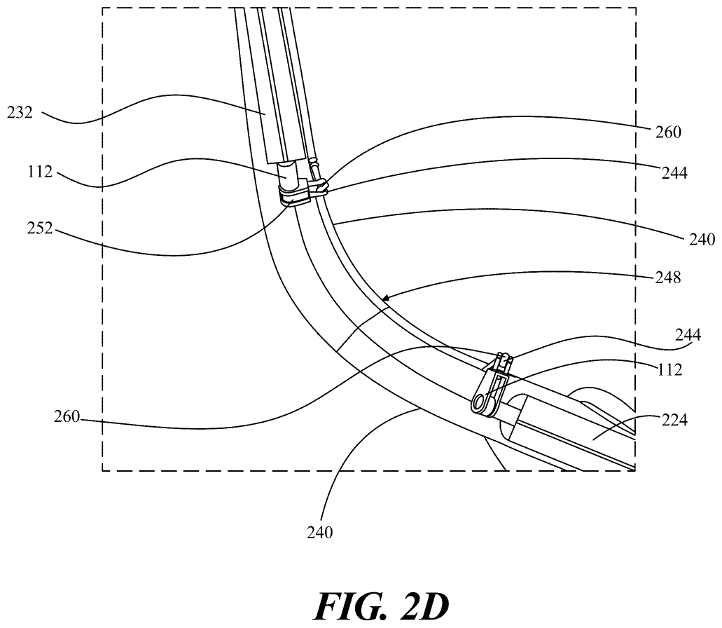

In one or more embodiments, actuators 112 may include pneumatic pistons, hydraulic pistons, and/or solenoid pistons. In other embodiments, actuators 112 may use electrical components. For example, as shown in FIGS. 2A-2C, actuators 112 may each include a hydraulic piston that extends or retracts to actuate flight component 104. In another example, actuators 112 may each include a solenoid. Similarly, actuators 112 may be triggered by electrical power, pneumatic pressure, hydraulic pressure, or the like. Actuators 112 may also include electrical motors, servomotors, cables, and the like, as discussed further below.

With continued reference to FIG. 1, system 100 also includes a pilot control 116 communicatively connected to each actuator 112 and configured to generate an attitude command 120 to the plurality of actuators 112. Pilot control 116 may include a pilot interfacing component. The pilot interfacing component may be an inceptor stick, collective pitch control, lift lever, brake pedals, pedal controls, steering wheel, throttle lever, throttle wheel, toggles, joystick, or control wheel. One of ordinary skill in the art, upon reading the entirety of this disclosure would appreciate the variety of input controls that may be present in an aircraft consistent with the present disclosure. Inceptor stick may be consistent with disclosure of inceptor stick in U.S. patent application Ser. No. 17/001,845 and titled “A HOVER AND THRUST CONTROL ASSEMBLY FOR DUAL-MODE AIRCRAFT”, which is incorporated herein by reference in its entirety. Collective pitch control may be consistent with disclosure of collective pitch control in U.S. patent application Ser. No. 16/929,206 and titled “HOVER AND THRUST CONTROL ASSEMBLY FOR DUAL-MODE AIRCRAFT”, which is incorporated herein by reference in its entirety. Additionally, or alternatively, pilot input 136 may include one or more data sources providing raw data. As used herein, “pilot input” is an input from a pilot to a pilot control. “Raw data”, for the purposes of this disclosure, is data representative of aircraft information that has not been conditioned, manipulated, or processed in a manner that renders data unrepresentative of aircraft information. In exemplary embodiments, pilot input 136 may be provided by a pilot or an automation system. Pilot input 136 may be exterior sensor data, interior sensor data, data retrieved from one or more remotely or onboard computing devices. Pilot input 136 may include audiovisual data, pilot voice data, biometric data, or a combination thereof. Pilot input 136 may include information or raw data gathered from gyroscopes, inertial measurement units (IMUs), motion sensors, a combination thereof, or another sensor or grouping of sensors. Pilot control 116 may be physically located in the cockpit of aircraft 108 or remotely located outside of aircraft 108 in another location communicatively connected to at least a portion of aircraft 108.

In one or more embodiments, one actuator 112 may be able to move flight component 104 if the other actuator 112 fails to move flight component 104 after receipt of attitude command 120 from pilot control 116. More specifically, second actuator 112b may be able to move flight component 104 if first actuator 112a is disabled and fails to actuate. For instance, and without limitation, if the first actuator 112a malfunctions, loses communication, or otherwise does not operate as intended, second actuator 112b may move flight component 104. Thus, actuators 112 are communicatively connected to receive data from pilot control 116 so that, if failure to actuate by one of actuators 112 is detected, the other actuator 112 actuates and moves flight component 104. For example, actuators 112 are communicatively connected to receive attitude command 120 from pilot control 116.

In one or more embodiments, actuators 112 may receive attitude command 120 from pilot control 116 and simultaneously actuate to move flight component 104 together. In other embodiments, only one actuator 112 may receive attitude command 120 to move flight component 104. For instance, and without limitation, first actuator 112a may receive attitude command 120 from pilot control 116 to move flight component 104. Then, if first actuator 112a fails to move flight component 104, second actuator 112b may move flight component 104, as discussed further in this disclosure. Actuators 112 may each include components, processors, computing devices, sensors, or the like. Actuators 112 may also include a computing device or plurality of computing devices consistent with the entirety of this disclosure. In one or more embodiments, pilot control 116 and/or actuators 112 may communicate with, receive commands from, and/or provide commands to flight controller 132, as discussed further below.

In reference still to FIG. 1, system 100 may include a sensor 124 that is communicatively connected to pilot control 116 and/or plurality of actuators 112. Sensor 124 may be attached to aircraft 108 or to actuators 112, as discussed further disclosure. In one or more embodiments, sensor 124 is configured to detect attitude command 120 from pilot control 116, detect disablement of first actuator 112a and/or disablement of second actuator 112b, and generate a failure datum 128 corresponding to the disablement. In one or more embodiments, pilot control 116 is configured to receive failure datum 128 from sensor 124 and, subsequently, generate attitude command 120 to second actuator 112b or first actuator 112a to move flight component 104 accordingly. In an embodiment, the actuator 112 that has not been disabled may be adjusted to move flight component 104 accordingly.

In one or more embodiments, sensor 124 may be configured to time all communication between first actuator 112a, second actuator 112b, and pilot control 116. Sensor 124 may detect that pilot control 116 has transmitted attitude command 120 to first actuator 112a and that flight component 104 has not moved in response to attitude command 120. As a result, sensor 124 may determine first actuator 112a is disabled and, thus, communicate to pilot control 116 and/or flight controller 132 that first actuator 112a is disabled. As a result, flight controller 132 may alert, for example, a pilot of the disablement and transmit a signal to second actuator 112b to actuate accordingly to move flight component 104. Though sensor 124 may be attached to aircraft 108 and communicating with each actuator 112a and 112b, as understood by one skilled in the art, in other embodiments, each actuator 112 may include a sensor.

In other embodiments, plurality of actuators 112 may simultaneously receive attitude command 120 and both actuate in response to move flight component 104. However, if first actuator 112a is disabled, sensor 124 is configured to detect the disablement and transmit failure datum 128 to pilot control 116 and to second actuator 112b so that second actuator 112b may adjust its operation accordingly. For example, second actuator 112b may, for example, increase power or torque to compensate for the failure of first actuator 112a so that flight component 104 moves as if first actuator 112a and second actuator 112b are operational.

Sensors, as described in this disclosure, are any device, module, and/or subsystems, utilizing any hardware, software, and/or any combination thereof to detect events and/or changes in the instant environment and communicate the information to the vehicle controller. Sensor 124 may be mechanically and/or communicatively connected, as described above, to aircraft 108. Sensor 124 may be configured to detect failure datum 128 of actuators 112. Sensor 124 may be incorporated into aircraft 108 or be remote. As an example, and without limitation, sensor 124 may be configured to detect disablement of one or more of the plurality of actuators 112 and generate failure datum 128 accordingly. Failure datum 128 may include, without limitation, an element of data identifying and/or describing a disablement of one or more of the plurality of actuators 112. In an embodiment, sensor 124 may detect that flight component 104 did not move despite a pilot input 136 into pilot control 116 and, thus, generate failure datum 128 in response. Failure datum 128 may include, as an example and without limitation, a determination that first actuator 112 is operating insufficiently, such as, for example, if first actuator 112 has been damaged or has lost communication.

In one or more embodiments, sensor 124 may include, as an example and without limitation, an environmental sensor. As used herein, an environmental sensor may be used to detect ambient temperature, barometric pressure, air velocity, motion sensors which may include gyroscopes, accelerometers, inertial measurement unit (IMU), various magnetic, humidity, and/or oxygen. As another non-limiting example, sensor 124 may include a geospatial sensor. As used in this disclosure, a geospatial sensor may include optical/radar/Lidar, GPS, and may be used to detect aircraft location, aircraft speed, aircraft altitude and whether the aircraft is on the correct location of the flight plan. Sensor 124 may be located inside aircraft 108. Sensor 124 may be inside a component of aircraft 108. In an embodiment, an environmental sensor may sense one or more environmental conditions or parameters outside the aircraft, inside the aircraft, or within or at any component thereof, including without limitation an energy source, a propulsor, or the like. The environmental sensor may further collect environmental information from the predetermined landing site, such as ambient temperature, barometric pressure, air velocity, motion sensors which may include gyroscopes, accelerometers, inertial measurement unit (IMU), various magnetic, humidity, and/or oxygen. The information may be collected from outside databases and/or information services, such as Aviation Weather Information Services. Sensor 124 may detect an environmental parameter, a temperature, a barometric pressure, a location parameter, and/or other necessary measurements. Sensor 124 may detect voltage, current, or other electrical connection via a direct method or by calculation. This may be accomplished, for instance, using an analog-to-digital converter, one or more comparators, or any other components usable to detect electrical parameters using an electrical connection that may occur to any person skilled in the art upon reviewing the entirety of this disclosure. Persons skilled in the art, upon reviewing the entirety of this disclosure, will be aware of various ways to monitor the status of the system of both critical and non-critical functions.

With continued reference to FIG. 1, flight controller 132 may be configured to receive an electrical parameter of actuators 112 from sensor 124. Such as, without limitation, flight controller 132 may be configured to receive failure datum 128 of actuators 112 from sensor 124. The electrical parameter of actuators 112 is any electrical parameter, as described in this disclosure. Flight controller 132 may be further configured to determine, using the electrical parameter, a power-production capability of the electrical energy source. Power-production capability, as described herein, is a capability to deliver power and/or energy to a load or component powered by an electrical energy source. A power-production capability may include a power delivery capability. As an example and without limitation, power delivery capability may include peak power output capability, average power output capability, a duration of time during which a given power level may be maintained, and/or a time at which a given power level may be delivered, including without limitation a peak and/or average power output capability. The time is provided in terms of a measurement of time in seconds and/or other units from a given moment, a measure of time in seconds and/or other units from a given point in a flight plan, or as a given point in a flight plan, such as, without limitation, a time when power may be provided may be rendered as a time at which an aircraft arrives at a particular stage in a flight plan. As an example and without limitation, power-production capability may indicate whether peak power may be provided at or during a landing stage of flight. Power-production capability may include, as a further example and without limitation, energy delivery capability, such as a total amount of remaining energy deliverable by a given electrical energy source, as well as one or more factors such as time, temperature, or rate that may affect the total amount of energy available. As a non-limiting example, circumstances that increase output impedance and/or resistance of an electrical energy source, and thus help determine in practical terms how much energy may actually be delivered to components, may be a part of energy delivery capability.

In one or more embodiments, sensor 124 may be a plurality of sensors incorporated in system 100 and/or aircraft 108. The plurality of sensors may be designed to detect a plurality of electrical parameters or environmental data in-flight, for instance as described above. The plurality of sensors may, as a non-limiting example, include a voltage sensor, wherein the voltage sensor is designed and configured to detect the voltage of one or more energy sources of aircraft 108 and/or actuators 112. As a further-non-limiting example, the plurality of sensors may include a current sensor, wherein the current sensor is designed and configured to detect the current of one or more energy sources of aircraft 108 and/or actuators 112. As a further non-limiting example, the plurality of sensors may include a temperature sensor, wherein the temperature sensor is designed and configured to detect the temperature of one or more energy sources of aircraft 108 and/or actuators 112. As a further non-limiting example, a plurality of sensors may include a resistance sensor, wherein the resistance sensor is designed and configured to detect the resistance of one or more energy sources of aircraft 108 and/or actuators 112. As another non-limiting example, a plurality of sensors may include an environmental sensor, wherein the environmental sensor may be designed and configured to detect a plurality of environmental data including, without limitation, ambient air temperature, barometric pressure, turbulence, and the like. The environmental sensor may be designed and configured, without limitation, to detect geospatial data to determine the location and altitude of the aircraft by any location method including, without limitation, GPS, optical, satellite, lidar, radar. The environmental sensor, as an example and without limitation, may be designed and configured to detect at a least a parameter of the motor. For example, environmental sensor may be designed and configured to detect motor of aircraft 108 or motor 220 of each actuator 112. The environmental sensor may be designed and configured, without limitation, to detect at a least a parameter of flight components 104. Sensor datum collected in flight, by sensors as described in this disclosure, may be transmitted to flight controller 132 and/or pilot control 116 and may be used to calculate the power output capacity of an energy source and/or projected energy needs of aircraft 108 during flight.

In one or more embodiments, pilot control 116 may include a processor configured to receive failure datum 128 from sensor 124. In one or more embodiments, pilot control 116 includes a pilot interfacing component. In one or more embodiments, pilot control 116 may communicate with the pilot interfacing component. In one or more exemplary embodiments, pilot interfacing component may be an inceptor, collective, foot brake, throttle lever, or control wheel. In one or more embodiments, pilot control 116 may also include buttons, switches, or other binary inputs in addition to, or alternatively than digital controls about which a plurality of inputs may be received. In one or more embodiments, pilot control 116 may be implemented as a flight controller, such as flight controller 132, as described in further detail in this disclosure.

Pilot control 116 may be configured to receive pilot input 136. Pilot input 136 may include a physical manipulation of a control, such as a pilot using a hand and arm to push or pull a lever, or a pilot using a finger to manipulate a switch. Pilot input 136 may include a voice command by a pilot to a microphone and computing system consistent with the entirety of this disclosure. Pilot control 116 is configured to generate an attitude command 120 as a function of pilot input 136. Pilot control 116 may be communicatively connected to any other component presented in system 100. The communicative connections may include redundant connections configured to safeguard against single-point failure. Pilot control 116 may include circuitry, computing devices, electronic components, or a combination thereof that translate pilot input 136 into at least an electronic signal, such as attitude command 120, configured to be transmitted to another electronic component.

Attitude command 120 may indicate a pilot's desire to change the heading or trim of an aircraft. “Attitude command”, for the purposes of this disclosure, refers to at least an element of data identifying a pilot input and/or command. Attitude command 120 may indicate a pilot's desire to change an aircraft's pitch, roll, or yaw. Pitch, roll, and yaw may correspond to three separate and distinct axes about which the aircraft may rotate with an applied moment, torque, and/or other force applied to at least a portion of an aircraft. The three axes may include a longitudinal axis, transverse axis, and yaw axis. “Longitudinal axis”, as used herein, refers to an imaginary axis that runs along the axis of symmetry of the fuselage. “Transverse axis”, as used herein, runs parallel to a line running from wing tip to wing tip of the aircraft, which is orthogonal to the longitudinal axis. “Yaw axis”, as used herein, is an imaginary axis that runs orthogonal to the longitudinal and transverse axis. “Pitch”, for the purposes of this disclosure refers to an aircraft's angle of attack, and is aircraft's rotation about the transverse axis. For example, an aircraft pitches “up” when the angle of attack is positive, like in a climb maneuver. In another example, the aircraft pitches “down”, when the angle of attack is negative, like in a dive maneuver. When angle of attack is not an acceptable input to any system disclosed herein, proxies may be used such as pilot controls, remote controls, or sensor levels, such as true airspeed sensors, pitot tubes, pneumatic/hydraulic sensors, and the like. “Roll” for the purposes of this disclosure, refers to rotation about an aircraft's longitudinal axis. “Yaw”, for the purposes of this disclosure, refers to rotation about the yaw axis. As used in this disclosure a “lift” is a perpendicular force to the oncoming flow direction of fluid surrounding the surface. For example, and without limitation relative air speed may be horizontal to aircraft 108, wherein lift force may be a force exerted in a vertical direction, directing aircraft 108 upwards. Attitude command 120 may be an electrical signal. Electrical signals may include analog signals, digital signals, periodic or aperiodic signal, step signals, unit impulse signal, unit ramp signal, unit parabolic signal, signum function, exponential signal, rectangular signal, triangular signal, sinusoidal signal, sine function, or pulse width modulated signal.

With continued reference to FIG. 1, pilot control 116 may be a mechanical and/or electrical component that causes actuators 112 to operate. In one or more embodiments, flight controller 132 may be communicatively connected to pilot control 116. For example, pilot control 116 may be controlled by flight controller 132. In another example, pilot control 116 may be a component of flight controller 132 (as shown in in FIG. 1). In other embodiments, pilot control 116 may be flight controller 132. “Flight controller”, for the purposes of this disclosure, refers to a component or grouping of components that control trajectory of the aircraft by taking in signals from a pilot and output signals to at least a propulsor and other portions of the aircraft, such as flight components, to adjust trajectory. Flight controller 132 may mix, refine, adjust, redirect, combine, separate, or perform other types of signal operations to translate pilot desired trajectory into aircraft maneuvers. Flight controller 132, for example, may take in pilot input 136 of moving an inceptor stick of pilot control 116. The signal from that move may be sent to flight controller 132, which performs any number or combinations of operations on those signals, then sends out output signals to any number of aircraft components that work in tandem or independently to maneuver the aircraft in response to the pilot input. Flight controller 132 may condition signals such that they can be sent and received by various components throughout aircraft 108.

Flight controller 132 may be designed and/or configured to perform any method, method step, or sequence of method steps in any embodiment described in this disclosure, in any order and with any degree of repetition. For instance, flight controller 132 may be configured to perform a single step or sequence repeatedly until a desired or commanded outcome is achieved. Repetition of a step or a sequence of steps may be performed iteratively and/or recursively using outputs of previous repetitions as inputs to subsequent repetitions, aggregating inputs and/or outputs of repetitions to produce an aggregate result, reduction or decrement of one or more variables such as global variables, and/or division of a larger processing task into a set of iteratively addressed smaller processing tasks. Flight controller 132 may perform any step or sequence of steps as described in this disclosure in parallel, such as simultaneously and/or substantially simultaneously performing a step two or more times using two or more parallel threads, processor cores, or the like; division of tasks between parallel threads and/or processes may be performed according to any protocol suitable for division of tasks between iterations. Persons skilled in the art, upon reviewing the entirety of this disclosure, will be aware of various ways in which steps, sequences of steps, processing tasks, and/or data may be subdivided, shared, or otherwise dealt with using iteration, recursion, and/or parallel processing. Flight controller 132, as well as any other components or combination of components, may be connected to a controller area network (CAN), which may interconnect all components for signal transmission and reception.

Additionally, flight controller 132 may include and/or communicate with any computing device, including without limitation a microcontroller, microprocessor, digital signal processor (DSP), and/or system on a chip (SoC). Flight controller 132 may be programmed to operate aircraft to perform at least a flight maneuver. At least a flight maneuver may include takeoff, landing, stability control maneuvers, emergency response maneuvers, regulation of altitude, roll, pitch, yaw, speed, acceleration, or the like during any phase of flight. At least a flight maneuver may include a flight plan or sequence of maneuvers to be performed during a flight plan. Flight controller 132 may be designed and configured to operate the aircraft via fly-by-wire. Flight controller 132 is communicatively connected to each actuator 112 and, thus, each flight component 104. As a non-limiting example, flight controller 132 may transmit signals to actuators 112 via an electrical circuit connecting flight controller 132 to actuators 112. The circuit may include a direct conductive path from flight controller 132 to actuators 112 or may include an isolated connection such as an optical or inductive connection. Alternatively, or additionally, flight controller 132 may communicate flight using wireless communication, such as without limitation communication performed using electromagnetic radiation including optical and/or radio communication, or communication via magnetic or capacitive connection. Flight controller 132 may be fully incorporated in an aircraft and may be a remote device operating the aircraft remotely via wireless or radio signals, or may be a combination thereof, such as a computing device in the aircraft configured to perform some steps or actions described in this disclosure while a remote device is configured to perform other steps. Persons skilled in the art will be aware, after reviewing the entirety of this disclosure, of many different forms and protocols of communication that may be used to communicatively connect flight controller 132 to actuators 112.

Flight controller 132 may interface or communicate with one or more additional devices as described below in further detail via a network interface device. Network interface device may be utilized for connecting flight controller 132 to one or more of a variety of networks, and one or more devices. Examples of a network interface device include, but are not limited to, a network interface card (e.g., a mobile network interface card, a LAN card), a modem, and any combination thereof. Examples of a network include, but are not limited to, a wide area network (e.g., the Internet, an enterprise network), a local area network (e.g., a network associated with an office, a building, a campus or other relatively small geographic space), a telephone network, a data network associated with a telephone/voice provider (e.g., a mobile communications provider data and/or voice network), a direct connection between two computing devices, and any combinations thereof. A network may employ a wired and/or a wireless mode of communication. In general, any network topology may be used. Information (e.g., data, software etc.) may be communicated to and/or from a computer and/or a computing device. Flight controller 132 may include but is not limited to, for example, a computing device or cluster of computing devices in a first location and a second computing device or cluster of computing devices in a second location. System 100 may include one or more computing devices dedicated to data storage, security, distribution of traffic for load balancing, and the like. Flight controller 132 may distribute one or more computing tasks as described below across a plurality of computing devices of computing device, which may operate in parallel, in series, redundantly, or in any other manner used for distribution of tasks or memory between computing devices. Flight controller 132 may be implemented using a “shared nothing” architecture in which data is cached at the worker, in an embodiment, this may enable scalability of flight controller 132 and/or computing device.

FIGS. 2A-2D show various partially transparent views of exemplary embodiments of actuators 112 of an exemplary aircraft 108. FIG. 2A shows an exemplary embodiment where actuators 112 are disposed within a wing 204 of aircraft 108 and attached to a portion of an airframe 208 of aircraft 108. Actuators 112 are also attached to aileron 212 so as to actuate movement of aileron 212. For example, as indicate by directional arrow 216, at least a portion of aileron 212 may be moved up or down relative to aircraft 108. Actuators 112 are each configured to move flight component 104 of aircraft 108 as a function of received attitude command 120 (shown in FIG. 1). Attitude command 120 indicates a desired change in aircraft attitude, as described in this disclosure.

In one or more exemplary embodiments, flight controller 132 and/or pilot control 116 is configured to generate attitude command 120 as a function of pilot input 136. For example, flight controller 132 may be configured to translate pilot input 136 using pilot control 116, in the form of moving an inceptor stick, for example, into electrical signals to actuators 112 that in turn, move flight component 104 of aircraft 108 in a way that manipulates a fluid medium, like air, to accomplish the pilot's desired maneuver. Attitude command 120 may be an electrical signal configured to be transmitted to at least a portion of aircraft 108, namely plurality of actuators 112, which are each attached to flight component 104 of aircraft 108 so that flight component 104 may manipulate a fluid medium to change the pitch, roll, yaw, or throttle of aircraft 108 when moved. In one or more embodiments, actuators 112 may include a conversion mechanism configured to convert the electrical signal from pilot control 116 to a mechanical movement of flight component 104. In one or more exemplary embodiments, actuators 112 may each include a piston and cylinder system configured to utilize hydraulic pressure to extend and retract a piston connected to at least a portion of aircraft 108.

In one or more embodiments, actuators 112 may each include a motor 220, as shown in FIGS. 2A-2C. For example, actuators 112 may each include a stepper motor or servomotor configured to utilize electrical energy into electromagnetic movement of a rotor in a stator. Actuators 112 may each include a system of gears attached to an electric motor configured to convert electrical energy into kinetic energy and mechanical movement through a system of gears. Motor 220 may be connected to an energy source. Motor 220 may be electrically connected to an inverter. Motor 220 may be powered by alternating current produced by the inverter. Each motor 220 may be operatively connected to each actuator 112. Motor 220 may operate to move one or more flight components 104, to drive one or more propulsors, or the like. Motor 220 may be driven by direct current (DC) electric power and may include, without limitation, brushless DC electric motors, switched reluctance motors, induction motors, or any combination thereof. A motor may also include electronic speed controllers, inverters, or other components for regulating motor speed, rotation direction, and/or dynamic braking.

In one or more embodiments, each actuator 112 may be attached to flight component 104. Each actuator 112 may be fixed, pivotally connected, or slidably connected to flight component 104. For example, actuator 112 may be pivotally connected to flight component 104 using a pivot joint, such as pivot joint 252 shown in FIGS. 2B-2D. In an exemplary embodiment, pivot joint 252 may be connected to a protrusion, such as protrusion 264, of flight component 104. When flight component is moved by one or more of actuators 112, flight component 104 may be rotated about a longitudinal axis of protrusion 264 such that at least a portion of flight component 104 is raised or lowered relative to outer-mold-lines (OML) 240 of aircraft 108 or raised or lowered to be flush with OML 240 of aircraft 108. Pivot joint may be a ball and socket joint, a condyloid joint, a saddle joint, a pin joint, pivot joint, a hinge joint, or a combination thereof. The pivot joint may allow for movement along a single axis or multiple axes. Actuators 112 may also include a rod 256, which directly or indirectly connects pivot joint 252 to motor 220. Rod 256 may have a rod end 260 that is connected to pivot joint 252. In one or more embodiments, rod 256 may be directly connected to motor 220 or connected to motor 220 via, for example, additional pivot joints.

With continued reference to FIG. 2A-2D, actuators 112 may each have a primary mode wherein each actuator 112 is configured to move flight component 104 of aircraft 108 as a function of attitude command 120 received from pilot control 116. Actuators 112 are configured to move flight component 104 of aircraft 108 in one or both of the two main modes of locomotion of flight component 104. For instance, without limitation, flight component 104 may be lifted, pivoted, or slid relative to OML 240 of aircraft 108 by actuators 112. For example, as shown in FIG. 2A, aileron 212 may be moved up or down relative to aircraft 108 (as indicated by directional arrow 216) by actuators 112. In another example, an elevator 224 of a horizontal stabilizer 228 may be moved up or down relative to aircraft 108 by actuators 112, as shown in FIGS. 2B and 2C. In another example, a rudder 232 of a vertical stabilizer 236 may be moved left or right relative to aircraft 108 by actuators 112, as shown in FIG. 2B. The electronic signals from pilot control 116 or flight controller 132 may be translated to flight component 104. For instance, without limitation, attitude command 120 from pilot control 116 or flight controller 132 may be translated to flight component 104. In one or more embodiments, flight component 104 includes an aerodynamic surface. In one or more exemplary embodiments, the aerodynamic surface may be an aileron, an edge slat, an elevator, a rudder, balance and anti-balance tabs, flaps, spoilers, a trim, or a mass balance.

In one or more embodiments, at least one of plurality of actuators 112 is enclosed in an outer-mold-lines (OML) 240 of aircraft 108, as shown in FIGS. 2A-2C. In other embodiments, at least a portion 244 of at least one of plurality of actuators 112 protrudes through OML 240 of aircraft 108, as shown in FIG. 2D. Furthermore, protruding portion 244 of at least one plurality of actuators 112 may be oriented relative to the OML so as to minimize drag.

FIG. 3A shows exemplary aircraft 108 with multiple pluralities of actuators 112a-c located in various locations and attached to various flight components 104 of aircraft 108. For example, plurality of actuators 112a are attached to and move ailerons 212 of wings 204. Plurality of actuators 112b are attached and move elevators 224 of horizontal stabilizers 228. Plurality of ailerons 112c are each attached to rudders 232 of vertical stabilizers 236. Though only two actuators are shown in each plurality of actuators 112a-c, more than two actuators may be used in each plurality of actuators 112a-c without changing the scope of the invention, as understood by one skilled on the art. Aircraft 108 may also include a plurality of flight controllers 132.

Now referring to FIG. 3B, another exemplary embodiment of aircraft 108 showing propulsors. As used in the current disclosure, a “propulsor” is a component and/or device used to propel a craft by exerting force on a fluid medium, which may include a gaseous medium such as air or a liquid medium such as water. In an embodiment, when a propulsor twists and pulls air behind it, it may, at the same time, push an aircraft forward with an amount of force and/or thrust. More air pulled behind an aircraft results in greater thrust with which the aircraft is pushed forward. Propulsor component may include any device or component that consumes electrical power on demand to propel an electric aircraft in a direction or other vehicle while on ground or in-flight. In an embodiment, propulsor component may include a puller component. As used in this disclosure a “puller component” is a component that pulls and/or tows an aircraft through a medium. As a non-limiting example, puller component may include a flight component such as a puller propeller, a puller motor, a puller propulsor, and the like. Additionally, or alternatively, puller component may include a plurality of puller flight components. In another embodiment, propulsor component may include a pusher component. As used in this disclosure a “pusher component” is a component that pushes and/or thrusts an aircraft through a medium. As a non-limiting example, pusher component may include a pusher component such as a pusher propeller, a pusher motor, a pusher propulsor, and the like. Additionally, or alternatively, pusher flight component may include a plurality of pusher flight components.

In another embodiment, and still referring to FIG. 3B, propulsor may include a propeller, a blade, or any combination of the two. A propeller may function to convert rotary motion from an engine or other power source into a swirling slipstream which may push the propeller forwards or backwards. Propulsor may include a rotating power-driven hub, to which several radial airfoil-section blades may be attached, such that an entire whole assembly rotates about a longitudinal axis. As a non-limiting example, blade pitch of propellers may be fixed at a fixed angle, manually variable to a few set positions, automatically variable (e.g. a “constant-speed” type), and/or any combination thereof as described further in this disclosure. As used in this disclosure a “fixed angle” is an angle that is secured and/or substantially unmovable from an attachment point. For example, and without limitation, a fixed angle may be an angle of 2.2° inward and/or 1.7° forward. As a further non-limiting example, a fixed angle may be an angle of 3.6° outward and/or 2.7° backward. In an embodiment, propellers for an aircraft may be designed to be fixed to their hub at an angle similar to the thread on a screw makes an angle to the shaft; this angle may be referred to as a pitch or pitch angle which may determine a speed of forward movement as the blade rotates. Additionally or alternatively, propulsor component may be configured having a variable pitch angle. As used in this disclosure a “variable pitch angle” is an angle that may be moved and/or rotated. For example, and without limitation, propulsor component may be angled at a first angle of 3.3° inward, wherein propulsor component may be rotated and/or shifted to a second angle of 1.7° outward.

In an embodiment, and still referring to FIG. 3B, lift propulsor 304 may be configured to produce a lift. As used in this disclosure a “lift propulsor” is a component that lifts an aircraft through a medium. In an embodiment, and without limitation, lift propulsor 304 may produce lift as a function of applying a torque to lift propulsor 304. As used in this disclosure a “torque” is a measure of force that causes an object to rotate about an axis in a direction. For example, and without limitation, torque may rotate an aileron and/or rudder to generate a force that may adjust and/or affect altitude, airspeed velocity, groundspeed velocity, direction during flight, and/or thrust. In some embodiments, lift propulsor 304 may be considered a puller component.

Still referring to FIG. 3B, as used in this disclosure a “thrust propulsor” is a component that pushes and/or thrusts an aircraft through a medium. As a non-limiting example, thrust propulsor 308 may include a pusher propeller, a paddle wheel, a pusher motor, a pusher propulsor, and the like. Thrust propulsor 308 may be primarily used in fixed wing-based flight. Thrust propulsor 308 may be located at the rear end of fuselage 312. Additionally, or alternatively, thrust propulsor 308 may include a plurality of pusher flight components. Thrust propulsor 308 is configured to produce a forward thrust. As a non-limiting example, forward thrust may include a force-to-force aircraft to in a horizontal direction along the longitudinal axis. As a further non-limiting example, thrust propulsor 308 may twist and/or rotate to pull air behind it and, at the same time, push aircraft 108 forward with an equal amount of force. In an embodiment, and without limitation, the more air forced behind aircraft, the greater the thrust force with which the aircraft is pushed horizontally will be. In another embodiment, and without limitation, forward thrust may force aircraft 108 through the medium of relative air. Additionally or alternatively, plurality of flight components may include one or more puller components. As used in this disclosure a “puller component” is a component that pulls and/or tows an aircraft through a medium. As a non-limiting example, puller component may include a flight component such as a puller propeller, a puller motor, a tractor propeller, a puller propulsor, and the like. Additionally, or alternatively, puller component may include a plurality of puller flight components.

Still referring to FIG. 3B, thrust propulsor 308 may include a thrust element which may be integrated into the propulsor. Thrust propulsor 308 may include, without limitation, a device using moving or rotating foils, such as one or more rotors, an airscrew or propeller, a set of airscrews or propellers such as contra-rotating propellers, a moving or flapping wing, or the like. Further, a Thrust propulsor 308, for example, can include without limitation a marine propeller or screw, an impeller, a turbine, a pump-jet, a paddle or paddle-based device, or the like.

In an embodiment and still referring to FIG. 3B, a plurality of lift propulsor 304 of plurality of flight components may be arranged in a quad copter orientation. As used in this disclosure a “quad copter orientation” is at least a lift component oriented in a geometric shape and/or pattern, wherein each of the lift components is located along a vertex of the geometric shape. For example, and without limitation, a square quad copter orientation may have four lift propulsor components oriented in the geometric shape of a square, wherein each of the four lift propulsor components are located along the four vertices of the square shape. As a further non-limiting example, a hexagonal quad copter orientation may have six lift components oriented in the geometric shape of a hexagon, wherein each of the six lift components are located along the six vertices of the hexagon shape. In an embodiment, and without limitation, quad copter orientation may include a first set of lift components and a second set of lift components, wherein the first set of lift components and the second set of lift components may include two lift components each, wherein the first set of lift components and a second set of lift components are distinct from one another. For example, and without limitation, the first set of lift components may include two lift components that rotate in a clockwise direction, wherein the second set of lift propulsor components may include two lift components that rotate in a counterclockwise direction. In an embodiment, and without limitation, the first set of lift components may be oriented along a line oriented 45° from the longitudinal axis of aircraft 108. In another embodiment, and without limitation, the second set of lift components may be oriented along a line oriented 135° from the longitudinal axis, wherein the first set of lift components line and the second set of lift components are perpendicular to each other.

Still referring to FIG. 3B, aircraft 108 may include an electric vertical takeoff and landing aircraft. As used herein, a vertical take-off and landing (eVTOL) aircraft is one that can hover, take off, and land vertically. An eVTOL, as used herein, is an electrically powered aircraft typically using an energy source, of a plurality of energy sources to power the aircraft. In order to optimize the power and energy necessary to propel the aircraft. eVTOL may be capable of rotor-based cruising flight, rotor-based takeoff, rotor-based landing, fixed-wing cruising flight, airplane-style takeoff, airplane-style landing, and/or any combination thereof. Rotor-based flight, as described herein, is where the aircraft generated lift and propulsion by way of one or more powered rotors coupled with an engine, such as a “quad copter,” multi-rotor helicopter, or other vehicle that maintains its lift primarily using downward thrusting propulsors. Fixed-wing flight, as described herein, is where the aircraft is capable of flight using wings and/or foils that generate lift caused by the aircraft's forward airspeed and the shape of the wings and/or foils, such as airplane-style flight. Boom 316 is located on aircraft 108, attached and adjacent to the fuselage 312. As used in this disclosure, a “boom” is an element that projects essentially horizontally from fuselage, including a laterally extending element, an outrigger, a spar, a lifting body, and/or a fixed wing that extends from fuselage 312. For the purposes of this disclosure, a “lifting body” is a structure that creates lift using aerodynamics. Boom 316 may extend perpendicularly to the fuselage 312.

Still referring to FIG. 3B, propellors of lift propulsors 304 may be configured to be parked in an aerodynamically efficient manner during fixed wing flight. As used in the current disclosure, the term “parked” refers to the propulsors being placed locked in a position parallel to boom 316 as shown in FIG. 1. Lift propulsors 304 may be used during flight modes that include hovering, vertical take-off and landing, and all rotor-based flight. Lift propulsors 304 will be parked during all fixed wing-based flight modes. In embodiments, a flight controller may signal to lift propulsors 304 that aircraft 108 is in engaged in fixed wing flight. Once this signal is received by lift propulsors 304 the propulsors will be locked into the parked position. In other embodiments, lift propulsors 304 may be parked in any position that is aerodynamically efficient. As used in the current disclosure, “aerodynamically efficient” is a measure of a designs to propensity to generate aerodynamic forces for efficient flight parameters. The most relevant consideration of aerodynamically efficiency is the lift/drag ratio. The propellors parked in a manner consistent with any method disclosed in disclosed in U.S. patent application Ser. No. 17/732,774, (Attorney Docket No. 1024-413USU1) filed on Apr. 29, 2022, and titled “SYSTEM FOR PROPELLER PARKING CONTROL FOR AN ELECTRIC AIRCRAFT AND A METHOD FOR ITS USE,” the entirety of which is hereby incorporated by reference.

Still referring to FIG. 3B, lift propulsors 304 and thrust propulsors 308 may be separate flight components. In embodiments, lift propulsors 304 and thrust propulsors 308 are two separate entities that separately perform the functions of lifting and thrusting aircraft 108 respectively. Separating these functions allows aircraft 108 to operate in a more efficient manner.

Still referring to FIG. 3B, aircraft 108 comprises a plurality of motor assembly and at least one boom 316 to house said motor assembly. Motor 220 assembly may be comprised of an electric, gas, etc. motor. Motor 220 is driven by electric power wherein power have varying or reversing voltage levels. For example, motor may be driven by alternating current (AC) wherein power is produced by an alternating current generator or inverter. Lift propulsors 304 and/or thrust propulsors 308 may be attached to a motor 220 assembly. For the purposes of this disclosure, an “electric motor,” is a machine that converts electrical energy into mechanical energy. Each electric motor 220 in system 100 includes a stator and at least an inverter. The motors of the current disclosure may be consistent with any motor disclosed in U.S. patent application Ser. No. 17/736,317, (Attorney Docket No. 1024-400USU1) filed on May 4, 2022, and titled “PROPULSOR ASSEMBLY POWERED BY A DUAL MOTOR SYSTEM,” the entirety of which is hereby incorporated by reference.

In an embodiment, and still referring to FIG. 3B, inverter may be configured to supply AC power to an electric propulsion unit (EPU) of aircraft 108. In an embodiment, an EPU may include motors, inverters, and propulsors. An “inverter”, as used herein, is a frequency converter that converts DC power into AC power. An inverter (also called a power inverter) may be entirely electronic or may include at least a mechanism (such as a rotary apparatus) and electronic circuitry. In some embodiments, static inverters may not use moving parts in conversion process. Inverters may not produce any power itself; rather, inverters may convert power produced by a DC power source. Inverters may often be used in electrical power applications where high currents and voltages are present; circuits that perform a similar function, as inverters, for electronic signals, having relatively low currents and potentials, may be referred to as oscillators. In some cases, circuits that perform opposite function to an inverter, converting AC to DC, may be referred to as rectifiers. Further description related to inverters and their use with electrical motors used on electric VTOL aircraft is disclosed within U.S. patent application Ser. No. 17/144,304 entitled “METHODS AND SYSTEMS FOR A FRACTIONAL CONCENTRATED STATOR CONFIGURED FOR USE IN ELECTRIC AIRCRAFT MOTOR” filed on Jan. 8, 2021 and by C. Lin et al. Additional descriptions related to inverters and electrical motors are disclosed in U.S. patent application Ser. No. 17/197,427 entitled “SYSTEM AND METHOD FOR FLIGHT CONTROL IN ELECTRIC AIRCRAFT” by T. Richter et al. and filed on Mar. 10, 2021.

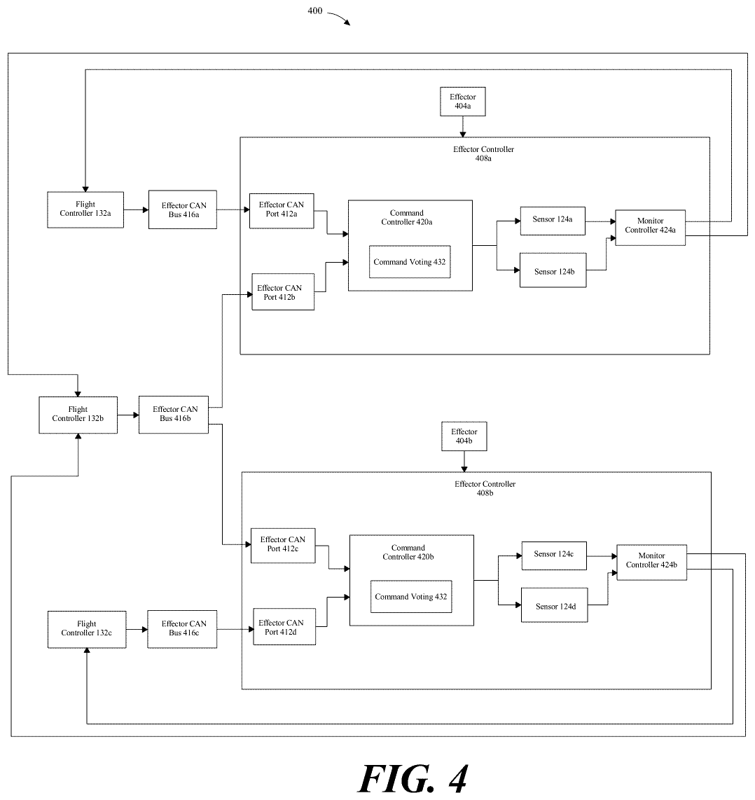

Now referencing FIG. 4, exemplary embodiment of a system 400 for reducing common mode failures in flight control of an aircraft is illustrated. As used herein, a “common mode failure” is an event or cause which bypasses or invalidates redundancy or independence. In some embodiments, common mode failure may include an event which causes the simultaneous loss of redundant or independent items which may or may not include inadvertent operation, or an unintended cascading effect from other operations or failure within the system. A common mode failure may include when two redundant actuators fail in the same way. For example, and without limitation, common mode failures may be caused by contamination (foreign objects, chemical degradation, internal generated debris, etc.), corrosion, environment (thermal conditions), loss of power, errors in software, saturation of signals (under sizing the data handling system), cascading (multi-channel systems with load sharing), maintenance or installation errors, and the like. In the case of software errors, hardware used may be redundant but the software is the same version on all units. Thus, if there is an error in the software, it may propagate throughout all hardware units (i.e. flight controllers). It may be important to have dissimilar components in an aircraft 108 to minimize common mode failures. As used herein, a “dissimilar component” is a component that performs substantially similar functions to another component but in different manners. For example, dissimilar components may include two monitoring sensors, one on a motor shaft and one on a gear shaft. Essentially, both sensors may monitor positioning of a motor but the motor shaft sensor may be located downstream of the gear shaft sensor. In another embodiment, dissimilar components may include different control logic. As used herein, “control logic” is a portion of a software that controls the operations. For example, dissimilar components, such as a command controller, monitor controller, sensors, and the like may have different code from each other (i.e. each command controller has different code). For example, a first dissimilar component may send a first signal to adjust the position of a rudder and a second dissimilar component may monitor the rudder deflection. Thus, the rudder is being adjusted and monitoring using different control logic and code in each dissimilar component. Additional information on dissimilar components is discussed below.

Still referencing FIG. 4, system 400 includes an effector 404. In some embodiments, there may be a plurality of effectors 404 in system 400, such as first effector 404a and second effector 404b. For example, aircraft 108 may include a dual motor system in the electric propulsion unit. Each motor (discussed above) may be redundant to each other. Each motor may be an effector. Effector 404a and effector 404b may be redundant, however within each effector 404, there may be dissimilar components. As used herein, an “effector” is an element that generates a force or moment on an electric aircraft. For example, an effector 404 may include an electric propulsion unit (EPU), an actuator 112 (discussed in FIG. 1-3), and the like. An EPU may include a motor, a lift propulsor, a pusher propulsor, and the like. In an embodiment, first effector 404a may be configured to control a first flight component 104 and a second effector 404b may be configured to control a second flight component 104 (shown in FIG. 1). For example, a first effector 404a may control a right aileron and a second effector 404b may control a left aileron. Flight component 104 may be any flight component as discussed herein. Each flight component 104 may include two redundant portions, flight component 104a and flight component 104b, which can be seen in FIG. 3. An effector 404 may be controlled by an effector controller 404. In an embodiment, an aircraft 108 may include a plurality of effector controllers 404, such as first effector controller 408a and second effector controller 408b. As used herein, an “effector controller” is a computing device configured to command an effector. Effector controller 408 may include a plurality of systems such as multiple computing devices. An effector controller 408 may include an inverter. Inverter may control a motor, EPU, or the like, which may be the effector.

Continuing to reference FIG. 4, first effector controller 408a is connected to a first effector 404a and includes a first effector controller area network (CAN) port 412a (also referred to as “first CAN port”) and a second effector CAN port 412b (also referred to as “second CAN port”). In an embodiment, a CAN port 412 may be connected to a CAN bus 416. For example, a first CAN port 412a may be connected to a first CAN bus 416a and a second CAN port 412b may be connected to a second CAN bus 416b. In another embodiment, second effector 404b may be connected to a second effector controller 408b and may include a third CAN port 412c and a fourth CAN port 412d. Third CAN port 412c may be connected to second CAN bus 416b. Fourth CAN port 412d may be connected to third CAN bus 416c. In an embodiment, there may be three CAN buses 416a-c communicatively connected to three flight controllers 132a-c, such that first CAN bus 416a may be communicatively connected to first flight controller 132a, second CAN bus 416b may be communicatively connected to second flight controller 132b, and third CAN bus 416c may be communicatively connected to third flight controller 132c. In an embodiment, flight controllers 132 may be redundant to each other. First flight controller 132a may be connected to the first effector CAN port 412a by first CAN bus 416a. Second flight controller 132b may be connected to both the second effector CAN port 412b and the third effector CAN port 412c by second CAN bus 416b. Third flight controller 132c may be connected to fourth effector CAN port 412d by third CAN bus 416c. “Connected” may refer to mechanical and/or communicative connections.

Still referencing FIG. 4, A “controller area network bus,” as used in this disclosure, is vehicle bus unit including a central processing unit (CPU), a CAN controller, and a transceiver designed to allow devices to communicate with each other's applications without the need of a host computer which is located physically at the aircraft. As used herein, a “CAN port” is a port where a device receives or transmits communication to the CAN bus. CAN bus 416 may include physical circuit elements that may use, for instance and without limitation, twisted pair, digital circuit elements/FGPA, microcontroller, or the like to perform, without limitation, processing and/or signal transmission processes and/or tasks; circuit elements may be used to implement CAN bus components and/or constituent parts as described in further detail below. CAN bus 416 may include multiplex electrical wiring for transmission of multiplexed signaling. CAN bus 416 may include message-based protocol(s), wherein the invoking program sends a message to a process and relies on that process and its supporting infrastructure to then select and run appropriate programing. A plurality of CAN buses 416 located at the aircraft 108 may include mechanical connection to the aircraft, wherein the hardware of the CAN bus 416 is integrated within the infrastructure of the aircraft 108. CAN bus 416 may be communicatively connected to the aircraft and/or with a plurality of devices. Devices may include flight controllers 132, effector controllers 408, dissimilar command controllers 420, dissimilar monitor controllers 424, and the like.

Still referring to FIG. 4, CAN buses 416 communicatively connected to an aircraft may include flight controller(s), battery terminals, gyroscope, accelerometer, proportional-integral-derivative controller, and the like, which may communicate directly with one another and to operating flight control devices, virtual machines, and other computing devices elsewhere. “Communicatively connected”, for the purposes of this disclosure, is a process whereby one device, component, or circuit is able to receive data from and/or transmit data to another device, component, or circuit; communicative connection may be performed by wired or wireless electronic communication, either directly or by way of one or more intervening devices or components. In an embodiment, communicative connection includes electrically coupling an output of one device, component, or circuit to an input of another device, component, or circuit. Communicative connecting may be performed via a bus or other facility for intercommunication between elements of a computing device. Communicative connecting may include indirect connections via “wireless” connection, low power wide area network, radio communication, optical communication, magnetic, capacitive, optical coupling, or the like. CAN bus 416 may be mechanically connected to each other within the aircraft wherein the physical infrastructure of the device is integrated into the aircraft for control and operation of various devices within the aircraft. CAN bus 416 may be communicatively connected with each other and/or to one or more other devices, such as via a CAN gateway. Communicatively connecting may include direct electrical wiring, such as is done within automobiles and aircraft. Communicatively connecting may include infrastructure for receiving and/or transmitting transmission signals, such as with sending and propagating an analogue or digital signal using wired, optical, and/or wireless electromagnetic transmission medium.

Still referencing FIG. 4, first effector controller 408a is configured to receive a first command signal from first flight controller 132a and a second command signal from second flight controller 132b. In another embodiment, second effector controller 408b may be configured to receive a second command signal from the second flight controller 132b and a third command signal from the third flight controller 132c. As used herein, a “command signal” is a signal including instructions to the effector. For example, a command signal may include a signal to rotate an actuator (which is an effector), activate an aileron, and the like. A command signal may also include instructions about torque for a propulsor. As used in this disclosure, a “signal” is any intelligible representation of data, for example from one device to another. A signal may include an optical signal, a hydraulic signal, a pneumatic signal, a mechanical, signal, an electric signal, a digital signal, an analog signal and the like. In some cases, a signal may be used to communicate with a computing device, for example by way of one or more ports. In some cases, a signal may be transmitted and/or received by a computing device for example by way of an input/output port. An analog signal may be digitized, for example by way of an analog to digital converter. In some cases, an analog signal may be processed, for example by way of any analog signal processing steps described in this disclosure, prior to digitization. In some cases, a digital signal may be used to communicate between two or more devices, including without limitation computing devices. In some cases, a digital signal may be communicated by way of one or more communication protocols, including without limitation internet protocol (IP), controller area network (CAN) protocols, serial communication protocols (e.g., universal asynchronous receiver-transmitter [UART]), parallel communication protocols (e.g., IEEE 128 [printer port]), and the like.

Continuing to reference FIG. 4, a first dissimilar command controller 420a may be configured to control the first effector 404a as a function of command voting 432 (also referred to as “voting algorithm”) and the first command signal and the second command signal. In another embodiment, a second dissimilar command controller 420b may be configured to control the second effector 404b as a function of command voting 432 and the second command signal and the third command signal. As used herein, a “command controller” is a computing device configured to receive a plurality of command signals and determine one command signal. For example, a command controller 420 may use command voting to determine a command signal. Each command controller 420a-b may be dissimilar. Specifically, each command controller 420a-b may use dissimilar computer software configuration items (CSCIs), dissimilar power supply units, dissimilar CPUs, and the like.

Still referencing FIG. 4, and as used herein, “command voting” is an algorithm that determines a command to be transmitted as a function of a plurality of commands. Command voting 432 may combine command signals to generate and/or output a combined command signal.

Combining may include without limitation any form of mathematical aggregation, such as a sum, a weighted sum, a product, a weighted product, a triangular norm such as a minimum, bounded product, algebraic product, drastic product, or the like, a triangular co-norm such as a maximum, bounded sum, algebraic sum, drastic sum, or the like, an average such as an arithmetic and/or geometric mean, or the like. One of ordinary skill in the art, after reviewing the entirety of this disclosure, would appreciate that averaging (finding the mean) of a plurality of command signals from a plurality of flight controllers 132 is only one example of mathematical or other operations suitable to take all “votes” into account when generating a combined command signal.

Additional disclosure on command voting can be found in U.S. patent application Ser. No. 17/515,416 (Attorney Docket No. 1024-082USC1) filed on Oct. 30, 2021 and entitled “METHOD AND SYSTEM FOR FLY-BY-WIRE FLIGHT CONTROL CONFIGURED FOR USE IN ELECTRIC AIRCRAFT,” which is incorporated by reference in its entirety herein.

Continuing to reference FIG. 4, first effector controller 408a is configured to detect a first output of the first effector 404a using a first dissimilar sensor 124a. As discussed above, dissimilar sensors may be dissimilar components, such that each sensor may operate in a different manner but perform similar functions. Additionally, first effector controller 408a is configured to detect a second output of the first effector 404a using a second dissimilar sensor 124b. In an embodiment, sensor 124a and sensor 124b may be dissimilar because they monitor different parts of the effector 404a. For example, sensor 124a may be a position sensor located on a gear shaft of a motor (which is effector 404a in this example) and sensor 124b may be a position sensor located on a motor shaft of a motor. Sensor 124a and sensor 124b may have different outputs but should be proportionally the same. Sensor 124 may be any position sensor such as a Hall effect sensor, quadrature sensor, rotary encoder (optical, magnetic, and the like), and the like. In another embodiment, second effector controller 408b may be configured to detect a first and second output of a second effector 404b using a third dissimilar sensor 124c and a fourth dissimilar sensor 124d.

In one or more embodiments, sensor 124 may include an encoder. As used herein, a “sensor” is a device which detects or measures a physical property. A detected measurement may include a direct reading of a speed or RPM of propulsor, which may be an output. Detected measurement may include measurements of other characteristics of propulsor that may be transmitted to flight controller 132. For example, a measurement of an actuation of a pilot control, such as a pushing of a throttle lever, may be used to identify a thrust envelope parameter. A pilot control may include, for example and without limitation, a wheel, pedal, button, switch, knob, lever, stick, or any other device and or mechanism used by a pilot to control movement of aircraft 108 through a medium. In one or more embodiments, sensor 124 may include one or more shaft (rotary type) encoder, photoelectric (optical type) sensor, and/or magnetic rotational speed (proximity type) sensor to detect an RPM or rotational speed of motor and/or propulsor of aircraft 108.

Still referring to FIG. 4, sensor 124 may include a motion sensor. A “motion sensor,” for the purposes of this disclosure, refers to a device or component configured to detect physical movement of an object or grouping of objects. One of ordinary skill in the art would appreciate, after reviewing the entirety of this disclosure, that motion may include a plurality of types including but not limited to: spinning, rotating, oscillating, gyrating, jumping, sliding, reciprocating, or the like. Sensor 124 may include, torque sensor, gyroscope, accelerometer, magnetometer, inertial measurement unit (IMU), pressure sensor, force sensor, proximity sensor, displacement sensor, vibration sensor, or the like. For example, without limitation, sensor 124 may include a gyroscope that is configured to detect a current aircraft orientation, such as roll angle.

In one or more embodiments, sensor 124 may include a plurality of weather sensors. In one or more embodiments, sensor 124 may include a wind sensor. In some embodiments, a wind sensor may be configured to measure a wind datum. A “wind datum” may include data of wind forces acting on an aircraft. Wind datum may include wind strength, direction, shifts, duration, or the like. For example, and without limitations, sensor 124 may include an anemometer. An anemometer may be configured to detect a wind speed. In one or more embodiments, the anemometer may include a hot wire, laser doppler, ultrasonic, and/or pressure anemometer. In some embodiments, sensor 124 may include a pressure sensor. “Pressure,” for the purposes of this disclosure and as would be appreciated by someone of ordinary skill in the art, is a measure of force required to stop a fluid from expanding and is usually stated in terms of force per unit area. The pressure sensor that may be included in sensor 124 may be configured to measure an atmospheric pressure and/or a change of atmospheric pressure. In some embodiments, the pressure sensor may include an absolute pressure sensor, a gauge pressure sensor, a vacuum pressure sensor, a differential pressure sensor, a sealed pressure sensor, and/or other unknown pressure sensors or alone or in a combination thereof. In one or more embodiments, a pressor sensor may include a barometer. In some embodiments, a pressure sensor may be used to indirectly measure fluid flow, speed, water level, and altitude. In some embodiments, the pressure sensor may be configured to transform a pressure into an analogue electrical signal. In some embodiments, the pressure sensor may be configured to transform a pressure into a digital signal.

In one or more embodiments, sensor 124 may include an altimeter that may be configured to detect an altitude of aircraft 108. In one or more embodiments, sensor 124 may include a moisture sensor. “Moisture,” as used in this disclosure, is the presence of water, this may include vaporized water in air, condensation on the surfaces of objects, or concentrations of liquid water. Moisture may include humidity. “Humidity,” as used in this disclosure, is the property of a gaseous medium (almost always air) to hold water in the form of vapor. In one or more embodiments, sensor 124 may include an altimeter. The altimeter may be configured to measure an altitude. In some embodiments, the altimeter may include a pressure altimeter. In other embodiments, the altimeter may include a sonic, radar, and/or Global Positioning System (GPS) altimeter. In some embodiments, sensor 124 may include a meteorological radar that monitors weather conditions. In some embodiments, sensor 124 may include a ceilometer. The ceilometer may be configured to detect and measure a cloud ceiling and cloud base of an atmosphere. In some embodiments, the ceilometer may include an optical drum and/or laser ceilometer. In some embodiments, sensor 124 may include a rain gauge. The rain gauge may be configured to measure precipitation. Precipitation may include rain, snow, hail, sleet, or other precipitation forms. In some embodiments, the rain gauge may include an optical, acoustic, or other rain gauge. In some embodiments, sensor 124 may include a pyranometer. The pyranometer may be configured to measure solar radiation. In some embodiments, the pyranometer may include a thermopile and/or photovoltaic pyranometer. The pyranometer may be configured to measure solar irradiance on a planar surface. In some embodiments, sensor 124 may include a lightning detector. The lightning detector may be configured to detect and measure lightning produced by thunderstorms. In some embodiments, sensor 124 may include a present weather sensor (PWS). The PWS may be configured to detect the presence of hydrometeors and determine their type and intensity. Hydrometeors may include a weather phenomenon and/or entity involving water and/or water vapor, such as, but not limited to, rain, snow, drizzle, hail and sleet. In some embodiments, sensor 124 may include an inertia measurement unit (IMU). The IMU may be configured to detect a change in specific force of a body.

In one or more embodiments, sensor 124 may include a local sensor. A local sensor may be any sensor mounted to aircraft 108 that senses objects or phenomena in the environment around aircraft 108. Local sensor may include, without limitation, a device that performs radio detection and ranging (RADAR), a device that performs lidar, a device that performs sound navigation ranging (SONAR), an optical device such as a camera, electro-optical (EO) sensors that produce images that mimic human sight, or the like. In one or more embodiments, sensor 124 may include a navigation sensor. For example, and without limitation, a navigation system of aircraft 108 may be provided that is configured to determine a geographical position of aircraft 108 during flight. The navigation may include a Global Positioning System (GPS), an Attitude Heading and Reference System (AHRS), an Inertial Reference System (IRS), radar system, and the like.

In one or more embodiments, sensor 124 may include electrical sensors. Electrical sensors may be configured to measure voltage across a component, electrical current through a component, and resistance of a component. In one or more embodiments, sensor 124 may include thermocouples, thermistors, thermometers, passive infrared sensors, resistance temperature sensors (RTD's), semiconductor based integrated circuits (IC), a combination thereof or another undisclosed sensor type, alone or in combination. Temperature, for the purposes of this disclosure, and as would be appreciated by someone of ordinary skill in the art, is a measure of the heat energy of a system. Temperature, as measured by any number or combinations of sensors present within sensor 124, may be measured in Fahrenheit (° F.), Celsius (° C.), Kelvin (° K), or another scale alone or in combination. The temperature measured by sensors may comprise electrical signals which are transmitted to their appropriate destination wireless or through a wired connection.

In one or more embodiments, sensor 124 may include a sensor suite which may include a plurality of sensors that may detect similar or unique phenomena. For example, in a non-limiting embodiment, sensor suite may include a plurality of accelerometers, a mixture of accelerometers and gyroscope. System 400 may include a plurality of sensors in the form of individual sensors or a sensor suite working in tandem or individually. A sensor suite may include a plurality of independent sensors, as described in this disclosure, where any number of the described sensors may be used to detect any number of physical or electrical quantities associated with an aircraft. Independent sensors may include separate sensors measuring physical or electrical quantities that may be powered by and/or in communication with circuits independently, where each may signal sensor output to a control circuit such as a user graphical interface. In an embodiment, use of a plurality of independent sensors may result in redundancy configured to employ more than one sensor that measures the same phenomenon, those sensors being of the same type, a combination of, or another type of sensor not disclosed, so that in the event one sensor fails, the ability to detect phenomenon is maintained.

Continuing to reference FIG. 4, first and second outputs from sensor 124a and sensor 124b may be received by a dissimilar monitor controller 424a within first effector controller 408a. In another embodiment, third and fourth outputs from sensor 124c and sensor 124b of the second effector 404b may be received by a dissimilar monitor controller 424b within second effector controller 408b. Monitor controller 424a and 424b may be dissimilar from command controller 420a and 420b, respectively. As used herein, a “monitor controller” is a computing device configured to monitor an effector. In an embodiment, monitor controller 424 may monitor by receiving outputs from a plurality of sensors and transmitting monitor signals to a flight controller 132. As used herein, a “monitor signal” is a signal relating to sensor outputs. For example, a sensor output may include an RPM that the gear shaft or motor shaft is rotating at. In an embodiment, a first monitor signal may be configured to be transmitted to the first flight controller 132a through a first dissimilar monitor controller 424a, and a second monitor signal may be transmitted to the second flight controller 132b through the first dissimilar monitor controller 424b. In another embodiment, a third monitor signal may be transmitted to the second flight controller 132b through a second dissimilar monitor controller 424b in the second effector controller 408b, and a fourth monitor signal may be transmitted to the third flight controller 132c through a second dissimilar monitor controller 424b. In an embodiment, the first effector controller 408a may be further configured to transmit a first monitor signal as a function of the first output to the first flight controller 132a and a second monitor signal as a function of the second output to the second flight controller 132b. In another embodiment, the second effector controller 408b may be further configured to transmit a third monitor signal as a function of the third output to the second flight controller 132b and a fourth monitor signal as a function of the fourth output to the third flight controller 132c.

Still referencing FIG. 4, system 400 may include three flight controllers 132. Second flight controller 132b may receive signals from both effector controller 408a and effector controller 408b. Second flight controller 132b may compare both monitor signals from both effector controllers 408a and 408b to ensure that both effectors 404a and 404b are operating correctly. Operating correctly may include responding appropriately to commands from the effector controllers 408, and the like.

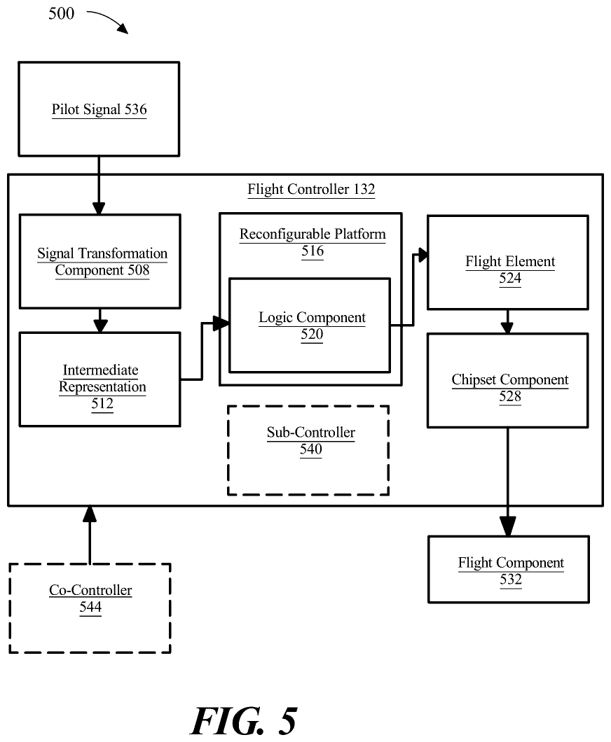

Now referring to FIG. 5, an exemplary embodiment 500 of a flight controller 132 is illustrated. As used in this disclosure a “flight controller” is a computing device of a plurality of computing devices dedicated to data storage, security, distribution of traffic for load balancing, and flight instruction. Flight controller 132 may include and/or communicate with any computing device as described in this disclosure, including without limitation a microcontroller, microprocessor, digital signal processor (DSP) and/or apparatus on a chip (SoC) as described in this disclosure. Further, flight controller 132 may include a single computing device operating independently, or may include two or more computing device operating in concert, in parallel, sequentially or the like; two or more computing devices may be included together in a single computing device or in two or more computing devices. In embodiments, flight controller 132 may be installed in an aircraft, may control the aircraft remotely, and/or may include an element installed in the aircraft and a remote element in communication therewith.

In an embodiment, and still referring to FIG. 5, flight controller 132 may include a signal transformation component 508. As used in this disclosure a “signal transformation component” is a component that transforms and/or converts a first signal to a second signal, wherein a signal may include one or more digital and/or analog signals. For example, and without limitation, signal transformation component 508 may be configured to perform one or more operations such as preprocessing, lexical analysis, parsing, semantic analysis, and the like thereof. In an embodiment, and without limitation, signal transformation component 508 may include one or more analog-to-digital convertors that transform a first signal of an analog signal to a second signal of a digital signal. For example, and without limitation, an analog-to-digital converter may convert an analog input signal to a 10-bit binary digital representation of that signal. In another embodiment, signal transformation component 508 may include transforming one or more low-level languages such as, but not limited to, machine languages and/or assembly languages. For example, and without limitation, signal transformation component 508 may include transforming a binary language signal to an assembly language signal. In an embodiment, and without limitation, signal transformation component 508 may include transforming one or more high-level languages and/or formal languages such as but not limited to alphabets, strings, and/or languages. For example, and without limitation, high-level languages may include one or more apparatus languages, scripting languages, domain-specific languages, visual languages, esoteric languages, and the like thereof. As a further non-limiting example, high-level languages may include one or more algebraic formula languages, business data languages, string and list languages, object-oriented languages, and the like thereof.

Still referring to FIG. 5, signal transformation component 508 may be configured to optimize an intermediate representation 512. As used in this disclosure an “intermediate representation” is a data structure and/or code that represents the input signal. Signal transformation component 508 may optimize intermediate representation as a function of a data-flow analysis, dependence analysis, alias analysis, pointer analysis, escape analysis, and the like thereof. In an embodiment, and without limitation, signal transformation component 508 may optimize intermediate representation 512 as a function of one or more inline expansions, dead code eliminations, constant propagation, loop transformations, and/or automatic parallelization functions. In another embodiment, signal transformation component 508 may optimize intermediate representation as a function of a machine dependent optimization such as a peephole optimization, wherein a peephole optimization may rewrite short sequences of code into more efficient sequences of code. Signal transformation component 508 may optimize intermediate representation to generate an output language, wherein an “output language,” as used herein, is the native machine language of flight controller 132. For example, and without limitation, native machine language may include one or more binary and/or numerical languages.

In an embodiment, and without limitation, signal transformation component 508 may include transform one or more inputs and outputs as a function of an error correction code. An error correction code, also known as error correcting code (ECC), is an encoding of a message or lot of data using redundant information, permitting recovery of corrupted data. An ECC may include a block code, in which information is encoded on fixed-size packets and/or blocks of data elements such as symbols of predetermined size, bits, or the like. Reed-Solomon coding, in which message symbols within a symbol set having q symbols are encoded as coefficients of a polynomial of degree less than or equal to a natural number k, over a finite field F with q elements; strings so encoded have a minimum hamming distance of k+1, and permit correction of (q−k−1)/2 erroneous symbols. Block code may alternatively or additionally be implemented using Golay coding, also known as binary Golay coding, Bose-Chaudhuri, Hocquenghuem (BCH) coding, multidimensional parity-check coding, and/or Hamming codes. An ECC may alternatively or additionally be based on a convolutional code.

In an embodiment, and still referring to FIG. 5, flight controller 132 may include a reconfigurable hardware platform 516. A “reconfigurable hardware platform,” as used herein, is a component and/or unit of hardware that may be reprogrammed, such that, for instance, a data path between elements such as logic gates or other digital circuit elements may be modified to change an algorithm, state, logical sequence, or the like of the component and/or unit. This may be accomplished with such flexible high-speed computing fabrics as field-programmable gate arrays (FPGAs), which may include a grid of interconnected logic gates, connections between which may be severed and/or restored to program in modified logic.

Still referring to FIG. 5, reconfigurable hardware platform 516 may include a logic component 520. As used in this disclosure a “logic component” is a component that executes instructions on output language. For example, and without limitation, logic component may perform basic arithmetic, logic, controlling, input/output operations, and the like thereof. Logic component 520 may include any suitable processor, such as without limitation a component incorporating logical circuitry for performing arithmetic and logical operations, such as an arithmetic and logic unit (ALU), which may be regulated with a state machine and directed by operational inputs from memory and/or sensors; logic component 520 may be organized according to Von Neumann and/or Harvard architecture as a non-limiting example. Logic component 520 may include, incorporate, and/or be incorporated in, without limitation, a microcontroller, microprocessor, digital signal processor (DSP), Field Programmable Gate Array (FPGA), Complex Programmable Logic Device (CPLD), Graphical Processing Unit (GPU), general purpose GPU, Tensor Processing Unit (TPU), analog or mixed signal processor, Trusted Platform Module (TPM), a floating point unit (FPU), and/or apparatus on a chip (SoC). In an embodiment, logic component 520 may include one or more integrated circuit microprocessors, which may contain one or more central processing units, central processors, and/or main processors, on a single metal-oxide-semiconductor chip. Logic component 520 may be configured to execute a sequence of stored instructions to be performed on the output language and/or intermediate representation 512. Logic component 520 may be configured to fetch and/or retrieve the instruction from a memory cache, wherein a “memory cache,” as used in this disclosure, is a stored instruction set on flight controller 132. Logic component 520 may be configured to decode the instruction retrieved from the memory cache to opcodes and/or operands. Logic component 520 may be configured to execute the instruction on intermediate representation 512 and/or output language. For example, and without limitation, logic component 520 may be configured to execute an addition operation on intermediate representation 512 and/or output language.

In an embodiment, and without limitation, logic component 520 may be configured to calculate a flight element 524. As used in this disclosure a “flight element” is an element of datum denoting a relative status of aircraft. For example, and without limitation, flight element 524 may denote one or more torques, thrusts, airspeed velocities, forces, altitudes, groundspeed velocities, directions during flight, directions facing, forces, orientations, and the like thereof. For example, and without limitation, flight element 524 may denote that aircraft is cruising at an altitude and/or with a sufficient magnitude of forward thrust. As a further non-limiting example, flight status may denote that is building thrust and/or groundspeed velocity in preparation for a takeoff. As a further non-limiting example, flight element 524 may denote that aircraft is following a flight path accurately and/or sufficiently.

Still referring to FIG. 5, flight controller 132 may include a chipset component 528. As used in this disclosure a “chipset component” is a component that manages data flow. In an embodiment, and without limitation, chipset component 528 may include a northbridge data flow path, wherein the northbridge dataflow path may manage data flow from logic component 520 to a high-speed device and/or component, such as a RAM, graphics controller, and the like thereof. In another embodiment, and without limitation, chipset component 528 may include a southbridge data flow path, wherein the southbridge dataflow path may manage data flow from logic component 520 to lower-speed peripheral buses, such as a peripheral component interconnect (PCI), industry standard architecture (ICA), and the like thereof. In an embodiment, and without limitation, southbridge data flow path may include managing data flow between peripheral connections such as ethernet, USB, audio devices, and the like thereof. Additionally or alternatively, chipset component 528 may manage data flow between logic component 520, memory cache, and a flight component 532. A flight component may be moved or adjusted to affect one or more flight elements. For example, flight component 632 may include a component used to affect the aircrafts' roll and pitch which may comprise one or more ailerons. As a further example, flight component 532 may include a rudder to control yaw of an aircraft. In an embodiment, chipset component 528 may be configured to communicate with a plurality of flight components as a function of flight element 524. For example, and without limitation, chipset component 528 may transmit to an aircraft rotor to reduce torque of a first lift propulsor and increase the forward thrust produced by a pusher component to perform a flight maneuver.

Still referring to FIG. 5, flight controller 132 may include, be included in, and/or communicate with a mobile device such as a mobile telephone or smartphone. Further, flight controller may communicate with one or more additional devices as described below in further detail via a network interface device. The network interface device may be utilized for commutatively connecting a flight controller to one or more of a variety of networks, and one or more devices. Examples of a network interface device include, but are not limited to, a network interface card (e.g., a mobile network interface card, a LAN card), a modem, and any combination thereof. Examples of a network include, but are not limited to, a wide area network (e.g., the Internet, an enterprise network), a local area network (e.g., a network associated with an office, a building, a campus or other relatively small geographic space), a telephone network, a data network associated with a telephone/voice provider (e.g., a mobile communications provider data and/or voice network), a direct connection between two computing devices, and any combinations thereof. The network may include any network topology and can may employ a wired and/or a wireless mode of communication.

In an embodiment, and still referring to FIG. 5, flight controller 132 may include, but is not limited to, for example, a cluster of flight controllers in a first location and a second flight controller or cluster of flight controllers in a second location. Flight controller 132 may include one or more flight controllers dedicated to data storage, security, distribution of traffic for load balancing, and the like. Flight controller 132 may be configured to distribute one or more computing tasks as described below across a plurality of flight controllers, which may operate in parallel, in series, redundantly, or in any other manner used for distribution of tasks or memory between computing devices. For example, and without limitation, flight controller 132 may implement a control algorithm to distribute and/or command the plurality of flight controllers. As used in this disclosure a “control algorithm” is a finite sequence of well-defined computer implementable instructions that may determine the flight component of the plurality of flight components to be adjusted. For example, and without limitation, control algorithm may include one or more algorithms that reduce and/or prevent aviation asymmetry. As a further non-limiting example, control algorithms may include one or more models generated as a function of a software including, but not limited to Simulink by MathWorks, Natick, Massachusetts, USA. In an embodiment, and without limitation, control algorithm may be configured to generate an auto-code, wherein an “auto-code,” is used herein, is a code and/or algorithm that is generated as a function of the one or more models and/or software's. In another embodiment, control algorithm may be configured to produce a segmented control algorithm. As used in this disclosure a “segmented control algorithm” is control algorithm that has been separated and/or parsed into discrete sections. For example, and without limitation, segmented control algorithm may parse control algorithm into two or more segments, wherein each segment of control algorithm may be performed by one or more flight controllers operating on distinct flight components.

In an embodiment, and still referring to FIG. 5, control algorithm may be configured to determine a segmentation boundary as a function of segmented control algorithm. As used in this disclosure a “segmentation boundary” is a limit and/or delineation associated with the segments of the segmented control algorithm. For example, and without limitation, segmentation boundary may denote that a segment in the control algorithm has a first starting section and/or a first ending section. As a further non-limiting example, segmentation boundary may include one or more boundaries associated with an ability of flight component 532. In an embodiment, control algorithm may be configured to create an optimized signal communication as a function of segmentation boundary. For example, and without limitation, optimized signal communication may include identifying the discrete timing required to transmit and/or receive the one or more segmentation boundaries. In an embodiment, and without limitation, creating optimized signal communication further comprises separating a plurality of signal codes across the plurality of flight controllers. For example, and without limitation the plurality of flight controllers may include one or more formal networks, wherein formal networks transmit data along an authority chain and/or are limited to task-related communications. As a further non-limiting example, communication network may include informal networks, wherein informal networks transmit data in any direction. In an embodiment, and without limitation, the plurality of flight controllers may include a chain path, wherein a “chain path,” as used herein, is a linear communication path comprising a hierarchy that data may flow through. In an embodiment, and without limitation, the plurality of flight controllers may include an all-channel path, wherein an “all-channel path,” as used herein, is a communication path that is not restricted to a particular direction. For example, and without limitation, data may be transmitted upward, downward, laterally, and the like thereof. In an embodiment, and without limitation, the plurality of flight controllers may include one or more neural networks that assign a weighted value to a transmitted datum. For example, and without limitation, a weighted value may be assigned as a function of one or more signals denoting that a flight component is malfunctioning and/or in a failure state.

Still referring to FIG. 5, the plurality of flight controllers may include a master bus controller. As used in this disclosure a “master bus controller” is one or more devices and/or components that are connected to a bus to initiate a direct memory access transaction, wherein a bus is one or more terminals in a bus architecture. Master bus controller may communicate using synchronous and/or asynchronous bus control protocols. In an embodiment, master bus controller may include flight controller 132. In another embodiment, master bus controller may include one or more universal asynchronous receiver-transmitters (UART). For example, and without limitation, master bus controller may include one or more bus architectures that allow a bus to initiate a direct memory access transaction from one or more buses in the bus architectures. As a further non-limiting example, master bus controller may include one or more peripheral devices and/or components to communicate with another peripheral device and/or component and/or the master bus controller. In an embodiment, master bus controller may be configured to perform bus arbitration. As used in this disclosure “bus arbitration” is method and/or scheme to prevent multiple buses from attempting to communicate with and/or connect to master bus controller. For example and without limitation, bus arbitration may include one or more schemes such as a small computer interface system, wherein a small computer interface system is a set of standards for physical connecting and transferring data between peripheral devices and master bus controller by defining commands, protocols, electrical, optical, and/or logical interfaces. In an embodiment, master bus controller may receive intermediate representation 512 and/or output language from logic component 520, wherein output language may include one or more analog-to-digital conversions, low bit rate transmissions, message encryptions, digital signals, binary signals, logic signals, analog signals, and the like thereof described above in detail.

Still referring to FIG. 5, master bus controller may communicate with a slave bus. As used in this disclosure a “slave bus” is one or more peripheral devices and/or components that initiate a bus transfer. For example, and without limitation, slave bus may receive one or more controls and/or asymmetric communications from master bus controller, wherein slave bus transfers data stored to master bus controller. In an embodiment, and without limitation, slave bus may include one or more internal buses, such as but not limited to a/an internal data bus, memory bus, system bus, front-side bus, and the like thereof. In another embodiment, and without limitation, slave bus may include one or more external buses such as external flight controllers, external computers, remote devices, printers, aircraft computer systems, flight control systems, and the like thereof.

In an embodiment, and still referring to FIG. 5, control algorithm may optimize signal communication as a function of determining one or more discrete timings. For example, and without limitation master bus controller may synchronize timing of the segmented control algorithm by injecting high priority timing signals on a bus of the master bus control. As used in this disclosure a “high priority timing signal” is information denoting that the information is important. For example, and without limitation, high priority timing signal may denote that a section of control algorithm is of high priority and should be analyzed and/or transmitted prior to any other sections being analyzed and/or transmitted. In an embodiment, high priority timing signal may include one or more priority packets. As used in this disclosure a “priority packet” is a formatted unit of data that is communicated between the plurality of flight controllers. For example, and without limitation, priority packet may denote that a section of control algorithm should be used and/or is of greater priority than other sections.

Still referring to FIG. 5, flight controller 132 may also be implemented using a “shared nothing” architecture in which data is cached at the worker, in an embodiment, this may enable scalability of aircraft and/or computing device. Flight controller 132 may include a distributer flight controller. As used in this disclosure a “distributer flight controller” is a component that adjusts and/or controls a plurality of flight components as a function of a plurality of flight controllers. For example, distributer flight controller may include a flight controller that communicates with a plurality of additional flight controllers and/or clusters of flight controllers.

Still referring to FIG. 5, flight controller may include a sub-controller 540. As used in this disclosure a “sub-controller” is a controller and/or component that is part of a distributed controller as described above; for instance, flight controller 132 may be and/or include a distributed flight controller made up of one or more sub-controllers. For example, and without limitation, sub-controller 540 may include any controllers and/or components thereof that are similar to distributed flight controller and/or flight controller as described above. Sub-controller 540 may include any component of any flight controller as described above. Sub-controller 540 may be implemented in any manner suitable for implementation of a flight controller as described above. As a further non-limiting example, sub-controller 540 may include one or more processors, logic components and/or computing devices capable of receiving, processing, and/or transmitting data across the distributed flight controller as described above. As a further non-limiting example, sub-controller 540 may include a controller that receives a signal from a first flight controller and/or first distributed flight controller component and transmits the signal to a plurality of additional sub-controllers and/or flight components.

Still referring to FIG. 5, flight controller may include a co-controller 544. As used in this disclosure a “co-controller” is a controller and/or component that joins flight controller 132 as components and/or nodes of a distributer flight controller as described above. For example, and without limitation, co-controller 544 may include one or more controllers and/or components that are similar to flight controller 132. As a further non-limiting example, co-controller 544 may include any controller and/or component that joins flight controller 132 to distributer flight controller. As a further non-limiting example, co-controller 544 may include one or more processors, logic components and/or computing devices capable of receiving, processing, and/or transmitting data to and/or from flight controller 132 to distributed flight control system. Co-controller 544 may include any component of any flight controller as described above. Co-controller 544 may be implemented in any manner suitable for implementation of a flight controller as described above.

In an embodiment, and with continued reference to FIG. 5, flight controller 132 may be designed and/or configured to perform any method, method step, or sequence of method steps in any embodiment described in this disclosure, in any order and with any degree of repetition. For instance, flight controller 132 may be configured to perform a single step or sequence repeatedly until a desired or commanded outcome is achieved; repetition of a step or a sequence of steps may be performed iteratively and/or recursively using outputs of previous repetitions as inputs to subsequent repetitions, aggregating inputs and/or outputs of repetitions to produce an aggregate result, reduction or decrement of one or more variables such as global variables, and/or division of a larger processing task into a set of iteratively addressed smaller processing tasks. Flight controller may perform any step or sequence of steps as described in this disclosure in parallel, such as simultaneously and/or substantially simultaneously performing a step two or more times using two or more parallel threads, processor cores, or the like; division of tasks between parallel threads and/or processes may be performed according to any protocol suitable for division of tasks between iterations. Persons skilled in the art, upon reviewing the entirety of this disclosure, will be aware of various ways in which steps, sequences of steps, processing tasks, and/or data may be subdivided, shared, or otherwise dealt with using iteration, recursion, and/or parallel processing.

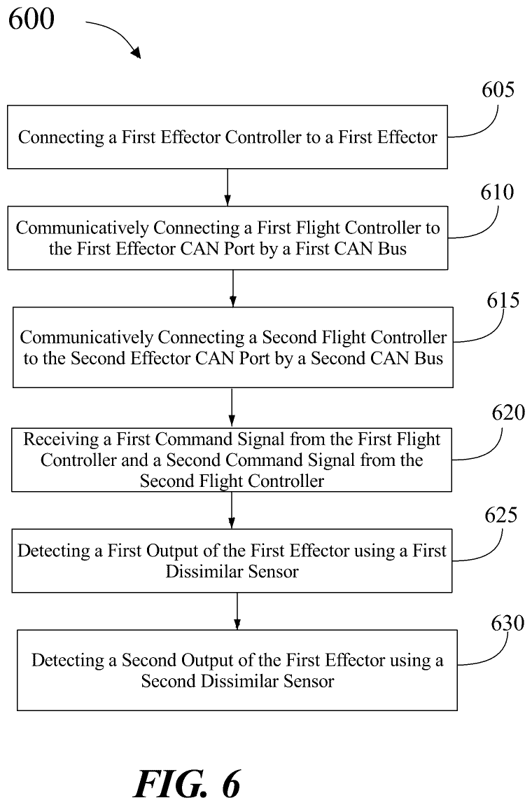

Now referring to FIG. 6, a method 600 for reducing common mode failure in flight control of an aircraft is shown. Step 605 of method 600 includes connecting a first effector controller to a first effector, wherein the first effector comprises a first effector CAN port and a second effector CAN port. The first effector may include an electric propulsion unit. This step may be implemented without limitation as described in FIGS. 1-5.

Method 600 may also include connecting a second effector controller to a second effector having a third effector CAN port communicatively connected to the second CAN bus and a fourth effector CAN port communicatively connected to a third CAN bus. The third CAN bus may be connected to a third flight controller. This may be implemented without limitation as described in FIGS. 1-5.

Step 610 of method 600 includes communicatively connecting a first flight controller to the first effector CAN port by a first CAN bus. This step may be implemented without limitation as described in FIGS. 1-5.

Step 615 of method 600 includes communicatively connecting a second flight controller to the second effector CAN port by a second CAN bus. This step may be implemented without limitation as described in FIGS. 1-5.

Step 620 of method 600 includes receiving, by the first effector controller, a first command signal from the first flight controller and a second command signal from the second flight controller. This step may be implemented without limitation as described in FIGS. 1-5.

Method 600 further may include controlling, by a first dissimilar command controller, the first effector as a function of command voting and the first command signal and the second command signal. The first effector controller may control a first flight component of an aircraft. The second effector controller may control a second flight component of an aircraft. Flight components may include air brakes and spoilers in addition to flight components discussed in FIGS. 1-5. This step may be implemented without limitation as described in FIGS. 1-5.

Step 625 of method 600 includes detecting, by the first effector controller, a first output of the first effector using a first dissimilar sensor. This step may be implemented without limitation as described in FIGS. 1-5.

Step 630 of method 600 may include detecting, by the first effector controller, a second output of the first effector using a second dissimilar sensor. Dissimilar components may include different control logic. This step may be implemented without limitation as described in FIGS. 1-5.

Method 600 also includes transmitting, by the first effector controller, a first monitor signal to the first flight controller, wherein the first monitor signal is a function of the first output, and a second monitor signal to the second flight controller, wherein the second monitor signal is a function of the second output. Method 600 also includes transmitting the first monitor signal to the first flight controller through a first dissimilar monitor controller which is dissimilar from the first dissimilar command controller.

It is to be noted that any one or more of the aspects and embodiments described herein may be conveniently implemented using one or more machines (e.g., one or more computing devices that are utilized as a user computing device for an electronic document, one or more server devices, such as a document server, etc.) programmed according to the teachings of the present specification, as will be apparent to those of ordinary skill in the computer art. Appropriate software coding can readily be prepared by skilled programmers based on the teachings of the present disclosure, as will be apparent to those of ordinary skill in the software art. Aspects and implementations discussed above employing software and/or software modules may also include appropriate hardware for assisting in the implementation of the machine executable instructions of the software and/or software module.

Such software may be a computer program product that employs a machine-readable storage medium. A machine-readable storage medium may be any medium that is capable of storing and/or encoding a sequence of instructions for execution by a machine (e.g., a computing device) and that causes the machine to perform any one of the methodologies and/or embodiments described herein. Examples of a machine-readable storage medium include, but are not limited to, a magnetic disk, an optical disc (e.g., CD, CD-R, DVD, DVD-R, etc.), a magneto-optical disk, a read-only memory “ROM” device, a random access memory “RAM” device, a magnetic card, an optical card, a solid-state memory device, an EPROM, an EEPROM, and any combinations thereof. A machine-readable medium, as used herein, is intended to include a single medium as well as a collection of physically separate media, such as, for example, a collection of compact discs or one or more hard disk drives in combination with a computer memory. As used herein, a machine-readable storage medium does not include transitory forms of signal transmission.

Such software may also include information (e.g., data) carried as a data signal on a data carrier, such as a carrier wave. For example, machine-executable information may be included as a data-carrying signal embodied in a data carrier in which the signal encodes a sequence of instruction, or portion thereof, for execution by a machine (e.g., a computing device) and any related information (e.g., data structures and data) that causes the machine to perform any one of the methodologies and/or embodiments described herein.

Examples of a computing device include, but are not limited to, an electronic book reading device, a computer workstation, a terminal computer, a server computer, a handheld device (e.g., a tablet computer, a smartphone, etc.), a web appliance, a network router, a network switch, a network bridge, any machine capable of executing a sequence of instructions that specify an action to be taken by that machine, and any combinations thereof. In one example, a computing device may include and/or be included in a kiosk.

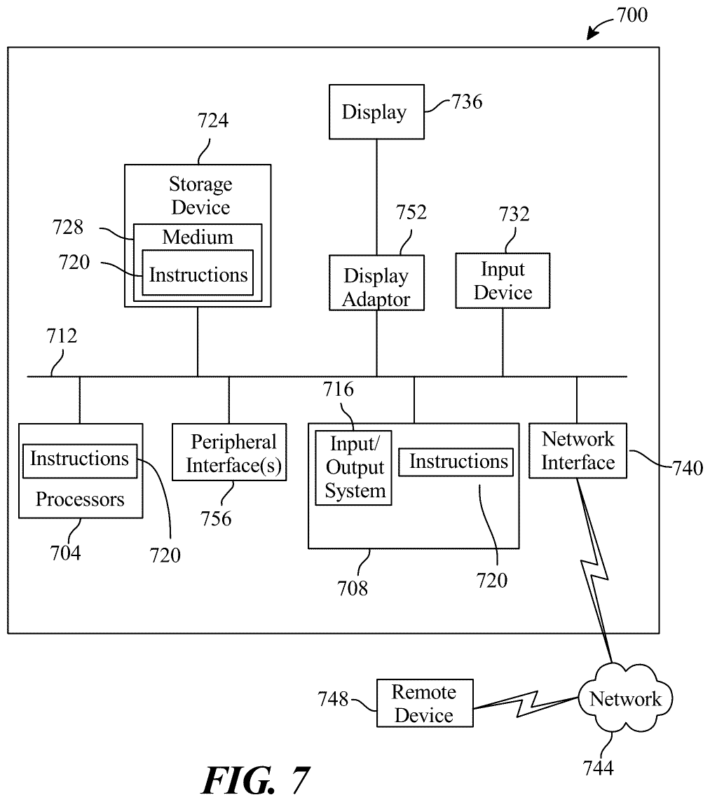

FIG. 7 shows a diagrammatic representation of one embodiment of a computing device in the exemplary form of a computer system 700 within which a set of instructions for causing a control system to perform any one or more of the aspects and/or methodologies of the present disclosure may be executed. It is also contemplated that multiple computing devices may be utilized to implement a specially configured set of instructions for causing one or more of the devices to perform any one or more of the aspects and/or methodologies of the present disclosure. Computer system 700 includes a processor 704 and a memory 708 that communicate with each other, and with other components, via a bus 712. Bus 712 may include any of several types of bus structures including, but not limited to, a memory bus, a memory controller, a peripheral bus, a local bus, and any combinations thereof, using any of a variety of bus architectures.

Processor 704 may include any suitable processor, such as without limitation a processor incorporating logical circuitry for performing arithmetic and logical operations, such as an arithmetic and logic unit (ALU), which may be regulated with a state machine and directed by operational inputs from memory and/or sensors; processor 704 may be organized according to Von Neumann and/or Harvard architecture as a non-limiting example. Processor 704 may include, incorporate, and/or be incorporated in, without limitation, a microcontroller, microprocessor, digital signal processor (DSP), Field Programmable Gate Array (FPGA), Complex Programmable Logic Device (CPLD), Graphical Processing Unit (GPU), general purpose GPU, Tensor Processing Unit (TPU), analog or mixed signal processor, Trusted Platform Module (TPM), a floating point unit (FPU), and/or system on a chip (SoC).

Memory 708 may include various components (e.g., machine-readable media) including, but not limited to, a random-access memory component, a read only component, and any combinations thereof. In one example, a basic input/output system 716 (BIOS), including basic routines that help to transfer information between elements within computer system 700, such as during start-up, may be stored in memory 708. Memory 708 may also include (e.g., stored on one or more machine-readable media) instructions (e.g., software) 720 embodying any one or more of the aspects and/or methodologies of the present disclosure. In another example, memory 708 may further include any number of program modules including, but not limited to, an operating system, one or more application programs, other program modules, program data, and any combinations thereof.

Computer system 700 may also include a storage device 724. Examples of a storage device (e.g., storage device 724) include, but are not limited to, a hard disk drive, a magnetic disk drive, an optical disc drive in combination with an optical medium, a solid-state memory device, and any combinations thereof. Storage device 724 may be connected to bus 712 by an appropriate interface (not shown). Example interfaces include, but are not limited to, SCSI, advanced technology attachment (ATA), serial ATA, universal serial bus (USB), IEEE 1394 (FIREWIRE), and any combinations thereof. In one example, storage device 724 (or one or more components thereof) may be removably interfaced with computer system 700 (e.g., via an external port connector (not shown)). Particularly, storage device 724 and an associated machine-readable medium 728 may provide nonvolatile and/or volatile storage of machine-readable instructions, data structures, program modules, and/or other data for computer system 700. In one example, software 720 may reside, completely or partially, within machine-readable medium 728. In another example, software 720 may reside, completely or partially, within processor 704.

Computer system 700 may also include an input device 732. In one example, a user of computer system 700 may enter commands and/or other information into computer system 700 via input device 732. Examples of an input device 732 include, but are not limited to, an alpha-numeric input device (e.g., a keyboard), a pointing device, a joystick, a gamepad, an audio input device (e.g., a microphone, a voice response system, etc.), a cursor control device (e.g., a mouse), a touchpad, an optical scanner, a video capture device (e.g., a still camera, a video camera), a touchscreen, and any combinations thereof. Input device 732 may be interfaced to bus 712 via any of a variety of interfaces (not shown) including, but not limited to, a serial interface, a parallel interface, a game port, a USB interface, a FIREWIRE interface, a direct interface to bus 712, and any combinations thereof. Input device 732 may include a touch screen interface that may be a part of or separate from display 736, discussed further below. Input device 732 may be utilized as a user selection device for selecting one or more graphical representations in a graphical interface as described above.

A user may also input commands and/or other information to computer system 700 via storage device 724 (e.g., a removable disk drive, a flash drive, etc.) and/or network interface device 740. A network interface device, such as network interface device 740, may be utilized for connecting computer system 700 to one or more of a variety of networks, such as network 744, and one or more remote devices 748 connected thereto. Examples of a network interface device include, but are not limited to, a network interface card (e.g., a mobile network interface card, a LAN card), a modem, and any combination thereof. Examples of a network include, but are not limited to, a wide area network (e.g., the Internet, an enterprise network), a local area network (e.g., a network associated with an office, a building, a campus or other relatively small geographic space), a telephone network, a data network associated with a telephone/voice provider (e.g., a mobile communications provider data and/or voice network), a direct connection between two computing devices, and any combinations thereof. A network, such as network 744, may employ a wired and/or a wireless mode of communication. In general, any network topology may be used. Information (e.g., data, software 720, etc.) may be communicated to and/or from computer system 700 via network interface device 740.

Computer system 700 may further include a video display adapter 752 for communicating a displayable image to a display device, such as display device 736. Examples of a display device include, but are not limited to, a liquid crystal display (LCD), a cathode ray tube (CRT), a plasma display, a light emitting diode (LED) display, and any combinations thereof. Display adapter 752 and display device 736 may be utilized in combination with processor 704 to provide graphical representations of aspects of the present disclosure. In addition to a display device, computer system 700 may include one or more other peripheral output devices including, but not limited to, an audio speaker, a printer, and any combinations thereof. Such peripheral output devices may be connected to bus 712 via a peripheral interface 756. Examples of a peripheral interface include, but are not limited to, a serial port, a USB connection, a FIREWIRE connection, a parallel connection, and any combinations thereof.

The foregoing has been a detailed description of illustrative embodiments of the invention. Various modifications and additions can be made without departing from the spirit and scope of this invention. Features of each of the various embodiments described above may be combined with features of other described embodiments as appropriate in order to provide a multiplicity of feature combinations in associated new embodiments. Furthermore, while the foregoing describes a number of separate embodiments, what has been described herein is merely illustrative of the application of the principles of the present invention. Additionally, although particular methods herein may be illustrated and/or described as being performed in a specific order, the ordering is highly variable within ordinary skill to achieve methods, systems, and software according to the present disclosure. Accordingly, this description is meant to be taken only by way of example, and not to otherwise limit the scope of this invention.

Exemplary embodiments have been disclosed above and illustrated in the accompanying drawings. It will be understood by those skilled in the art that various changes, omissions and additions may be made to that which is specifically disclosed herein without departing from the spirit and scope of the present invention.

1. A system for reducing common mode failures in flight control of an aircraft, the system comprising:
a first effector controller connected to a first effector and comprising a first effector CAN port and a second effector CAN port;
a first flight controller communicatively connected to the first effector CAN port by a first CAN bus;
a second flight controller communicatively connected to the second effector CAN port by a second CAN bus;
wherein, the first effector controller is configured to:
receive a first command signal from the first flight controller and a second command signal from the second flight controller, both signals received as a function a pilot input;
detect a first output of the first effector using a first dissimilar sensor; and
detect a second output of the first effector using a second dissimilar sensor; and
detect a failure datum of the first effector based on the first output and the second output, wherein the failure datum comprises data identifying a disablement of the first effector in response to the pilot input.

2. The system of claim 1, wherein the first effector controller is further configured to transmit a first monitor signal to the first flight controller, wherein the first monitor signal is a function of the first output, and a second monitor signal to the second flight controller, wherein the second monitor signal is a function of the second output.

3. The system of claim 1, further comprising a second effector controller connected to a second effector having a third effector CAN port communicatively connected to the second CAN bus and a fourth effector CAN port communicatively connected to a third CAN bus.

4. The system of claim 3, wherein the third CAN bus is communicatively connected to a third flight controller.

5. The system of claim 1, wherein the first dissimilar sensor and the second dissimilar sensor comprise different control logic.

6. The system of claim 1, wherein a first dissimilar command controller is configured to control the first effector as a function of command voting between the first command signal and the second command signal.

7. The system of claim 2, wherein the first monitor signal is configured to be transmitted to the first flight controller through a first dissimilar monitor controller which is dissimilar from a first dissimilar command controller.

8. The system of claim 1, wherein the first effector controller is configured to control a first flight component of an aircraft.

9. The system of claim 3, wherein the second effector controller is configured to control a second flight component of an aircraft.

10. The system of claim 1, wherein the first effector comprises an electric propulsion unit.

11. A method for reducing common mode failure in flight control of an aircraft, the method comprising:
connecting a first effector controller to a first effector, wherein the first effector comprises a first effector CAN port and a second effector CAN port;
communicatively connecting a first flight controller to the first effector CAN port by a first CAN bus;
communicatively connecting a second flight controller to the second effector CAN port by a second CAN bus;
receiving, by the first effector controller, a first command signal from the first flight controller and a second command signal from the second flight controller, both signals received as a function a pilot input;
detecting, by the first effector controller, a first output of the first effector using a first dissimilar sensor; and
detecting, by the first effector controller, a second output of the first effector using a second dissimilar sensor; and
detecting, by the first effector controller, a failure datum of the first effector based on the first output and the second output, wherein the failure datum comprises data identifying a disablement of the first effector in response to the pilot input.

12. The method of claim 11, further comprising transmitting, by the first effector controller, a first monitor signal to the first flight controller, wherein the first monitor signal is a function of the first output, and a second monitor signal to the second flight controller, wherein the second monitor signal is a function of the second output.

13. The method of claim 11, further comprising connecting a second effector controller to a second effector having a third effector CAN port communicatively connected to the second CAN bus and a fourth effector CAN port communicatively connected to a third CAN bus.

14. The method of claim 13, further comprising communicatively connecting the third CAN bus to a third flight controller.

15. The method of claim 11, wherein the first dissimilar sensor and the second dissimilar sensor comprise different control logic.

16. The method of claim 11, further comprising controlling, by a first dissimilar command controller, the first effector as a function of command voting between the first command signal and the second command signal.

17. The method of claim 12, further comprising transmitting the first monitor signal to the first flight controller through a first dissimilar monitor controller which is dissimilar from a first dissimilar command controller.

18. The method of claim 11, further comprising controlling, by the first effector controller, a first flight component of an aircraft.

19. The method of claim 13, further comprising controlling, by the second effector controller, a second flight component of an aircraft.

20. The method of claim 11, wherein the first effector comprises an electric propulsion unit.
